(19) United States
(12) Patent Application Publication
(10) Pub. No.: US 2024/0274630 A1
(43) Pub. Date: Aug. 15, 2024

(54) LIGHT DETECTING DEVICE AND ELECTRONIC APPARATUS

(71) Applicant: SONY SEMICONDUCTOR SOLUTIONS CORPORATION, Kanagawa (JP)

(72) Inventor: Tadashi IIJIMA, Kanagawa (JP)

(73) Assignee: SONY SEMICONDUCTOR SOLUTIONS CORPORATION, Kanagawa (JP)

(21) Appl. No.: 18/568,584

(22) PCT Filed: Feb. 10, 2022
(86) PCT No.: PCT/JP2022/005251

§ 371 Date: Dec. 8, 2023

(30) Foreign Application Priority Data
Jun. 24, 2021 (JP) 2021-104642

(51) Int. Cl. H01L 27/146

(52) U.S. Cl. CPC H01L 27/14623; H01L 27/1463; H01L 27/14636

(57) ABSTRACT

The present disclosure relates to a light detecting device and an electronic apparatus that can improve sensor characteristics. Provided is a light detecting device including a plurality of pixels each having a photoelectric conversion region, a structural body being formed in a lattice manner as viewed in plan on a semiconductor substrate in which the photoelectric conversion region is formed, the structural body having a first film including a first material and a second film including a second material different from the first material. The present disclosure is applicable to a CMOS solid-state imaging device, for example.

### TECHNICAL FIELD

The present disclosure relates to a light detecting device and an electronic apparatus, and particularly relates to a light detecting device and an electronic apparatus that can improve sensor characteristics.

### BACKGROUND ART

In a solid-state imaging device, a configuration is known which has an inter-pixel light shielding film formed between pixels adjacent to each other. PTL 1 discloses a structure in which the inter-pixel light shielding film is formed so as to penetrate an antireflection film and be in contact with a trench.

### CITATION LIST

### Patent Literature

PTL 1: U.S. Patent Application Publication No. 2020/0083268

### SUMMARY

### Technical Problems

However, with a technology disclosed in PTL 1, sufficient sensor characteristics may not be able to be obtained. There is thus a desire to improve the sensor characteristics.

The present disclosure has been made in view of such circumstances. The present disclosure is to make it possible to improve sensor characteristics.

### Solution to Problems

A light detecting device according to an aspect of the present disclosure is a light detecting device including a plurality of pixels each having a photoelectric conversion region, in which a structural body is formed in a lattice manner as viewed in plan on a semiconductor substrate in which the photoelectric conversion region is formed, the structural body having a first film including a first material and a second film including a second material different from the first material.

An electronic apparatus according to an aspect of the present disclosure is an electronic apparatus including a light detecting device, the light detecting device including a plurality of pixels each having a photoelectric conversion region, in which a structural body is formed in a lattice manner as viewed in plan on a semiconductor substrate in which the photoelectric conversion region is formed, the structural body having a first film including a first material and a second film including a second material different from the first material.

In the light detecting device according to an aspect of the present disclosure and the electronic apparatus, a plurality of pixels each having a photoelectric conversion region are provided, and a structural body having a first film including a first material and a second film including a second material different from the first material is formed in a lattice manner as viewed in plan on a semiconductor substrate in which the photoelectric conversion region is formed.

A light detecting device according to an aspect of the present disclosure is a light detecting device including a plurality of pixels each having a photoelectric conversion region, in which a conductor is formed in an element isolation region formed in a semiconductor substrate in which the photoelectric conversion region is formed, and a potential is applied to the conductor, and a structural body is formed in a lattice manner as viewed in plan on the semiconductor substrate, the structural body having a first film including a first material, a second film including a second material different from the first material, and a third film including a third material different from the first material and the second material.

An electronic apparatus according to an aspect of the present disclosure is an electronic apparatus including a light detecting device including a plurality of pixels each having a photoelectric conversion region, in which a conductor is formed in an element isolation region formed in a semiconductor substrate in which the photoelectric conversion region is formed, and a potential is applied to the conductor, and a structural body is formed in a lattice manner as viewed in plan on the semiconductor substrate, the structural body having a first film including a first material, a second film including a second material different from the first material, and a third film including a third material different from the first material and the second material.

In the light detecting device according to an aspect of the present disclosure and the electronic apparatus, a plurality of pixels each having a photoelectric conversion region are provided, a conductor is formed in an element isolation region formed in a semiconductor substrate in which the photoelectric conversion region is formed, and a potential is applied to the conductor, and a structural body having a first film including a first material, a second film including a second material different from the first material, and a third film including a third material different from the first material and the second material is formed in a lattice manner as viewed in plan on the semiconductor substrate.

Incidentally, the light detecting device according to an aspect of the present disclosure may be an independent device, or may be an internal block constituting one device.

### BRIEF DESCRIPTION OF DRAWINGS

FIG. 1 is a diagram illustrating an example of a configuration of a solid-state imaging device.

FIG. 2 is a diagram illustrating a first example of a structure including a pixel 100.

FIG. 3 is a diagram illustrating an example of a manufacturing method including processes for forming the structure of FIG. 1.

FIG. 4 is a diagram illustrating an example of a manufacturing method including processes for forming the structure of FIG. 1.

FIG. 5 is a diagram illustrating a second example of the structure including the pixel 100.

FIG. 6 is a diagram illustrating a third example of the structure including the pixel 100.

FIG. 7 is a diagram illustrating a fourth example of the structure including the pixel 100.

FIG. 8 is a diagram illustrating an example of a manufacturing method including processes for forming the structure of FIG. 7.

FIG. 9 is a diagram illustrating an example of a manufacturing method including processes for forming the structure of FIG. 7.

FIG. 10 is a diagram illustrating a fifth example of the structure including the pixel 100.

FIG. 11 is a diagram illustrating an example of a manufacturing method including processes for forming the structure of FIG. 10.

FIG. 12 is a diagram illustrating an example of a manufacturing method including processes for forming the structure of FIG. 10.

FIG. 13 is a diagram illustrating a sixth example of the structure including the pixel 100.

FIG. 14 is a diagram illustrating an example of a manufacturing method including processes for forming the structure of FIG. 13.

FIG. 15 is a diagram illustrating an example of a manufacturing method including processes for forming the structure of FIG. 13.

FIG. 16 is a diagram illustrating a seventh example of the structure including the pixel 100.

FIG. 17 is a diagram illustrating an eighth example of the structure including the pixel 100.

FIG. 18 is a diagram illustrating a ninth example of the structure including the pixel 100.

FIG. 19 is a diagram illustrating an example of a manufacturing method including processes for forming the structure of FIG. 18.

FIG. 20 is a diagram illustrating an example of a manufacturing method including processes for forming the structure of FIG. 18.

FIG. 21 is a diagram illustrating a tenth example of the structure including the pixel 100.

FIG. 22 is a diagram illustrating an eleventh example of the structure including the pixel 100.

FIG. 23 is a diagram of assistance in explaining the gist of a first embodiment.

FIG. 24 is a diagram illustrating a first example of a structure including a pixel 200.

FIG. 25 is a diagram illustrating an example of a manufacturing method including processes for forming the structure of FIG. 24.

FIG. 26 is a diagram illustrating an example of a manufacturing method including processes for forming the structure of FIG. 24.

FIG. 27 is a diagram illustrating a second example of the structure including the pixel 200.

FIG. 28 is a diagram illustrating a third example of the structure including the pixel 200.

FIG. 29 is a diagram illustrating an example of a manufacturing method including processes for forming the structure of FIG. 28.

FIG. 30 is a diagram illustrating an example of a manufacturing method including processes for forming the structure of FIG. 28.

FIG. 31 is a diagram illustrating a fourth example of the structure including the pixel 200.

FIG. 32 is a diagram illustrating a fifth example of the structure including the pixel 200.

FIG. 33 is a diagram illustrating an example of a manufacturing method including processes for forming the structure of FIG. 32.

FIG. 34 is a diagram illustrating an example of a manufacturing method including processes for forming the structure of FIG. 32.

FIG. 35 is a diagram illustrating a sixth example of the structure including the pixel 200.

FIG. 36 is a diagram illustrating a seventh example of the structure including the pixel 200.

FIG. 37 is a diagram illustrating an example of a manufacturing method including processes for forming the structure of FIG. 36.

FIG. 38 is a diagram illustrating an example of a manufacturing method including processes for forming the structure of FIG. 36.

FIG. 39 is a diagram illustrating an example of a manufacturing method including processes for forming the structure of FIG. 36.

FIG. 40 is a diagram illustrating an eighth example of the structure including the pixel 200.

FIG. 41 is a diagram of assistance in explaining the gist of a second embodiment.

FIG. 42 is a diagram of assistance in explaining the gist of the second embodiment.

FIG. 43 is a diagram illustrating an example of a configuration of an electronic apparatus.

### DESCRIPTION OF EMBODIMENTS

### Configuration of Solid-State Imaging Device

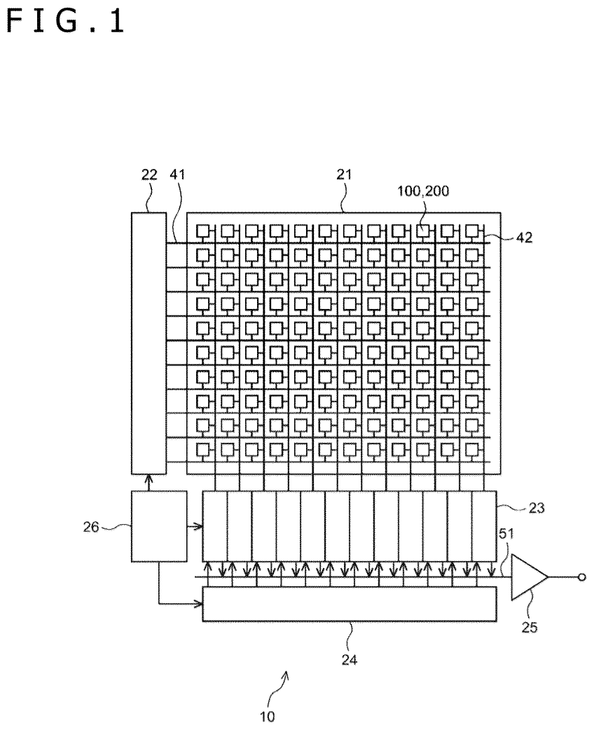

FIG. 1 is a diagram illustrating an example of a configuration of a solid-state imaging device.

In FIG. 1, a solid-state imaging device 10 is a CMOS (Complementary Metal Oxide Semiconductor) type solid-state imaging device. The solid-state imaging device 10 is an example of a light detecting device to which the present disclosure is applied. The solid-state imaging device 10 includes a pixel array unit 21, a vertical driving unit 22, a column signal processing unit 23, a horizontal driving unit 24, an output unit 25, and a control unit 26.

The pixel array unit 21 has a plurality of pixels 100 arranged two-dimensionally on a substrate including silicon (Si). A pixel 100 includes a photoelectric conversion region including a photodiode and a plurality of pixel transistors. The pixel transistors include a transfer transistor, a reset transistor, a selecting transistor, and an amplifier transistor.

Pixel driving lines 41 are formed for respective rows of the plurality of pixels 100 arranged two-dimensionally in the pixel array unit 21, and are connected to the vertical driving unit 22. Vertical signal lines 42 are formed for respective columns of the plurality of pixels 100, and are connected to the column signal processing unit 23.

The vertical driving unit 22 is constituted by a shift register, an address decoder, or the like. The vertical driving unit 22 drives each of the pixels 100 arranged in the pixel array unit 21. Pixel signals output from pixels 100 selected and scanned by the vertical driving unit 22 are supplied to the column signal processing unit 23 through the vertical signal lines 42.

The column signal processing unit 23 subjects the pixel signals output from the respective pixels 100 in a selected row through the vertical signal lines 42 to predetermined signal processing for each pixel column of the pixel array unit 21, and temporarily retains the pixel signals after the signal processing. Processing such, for example, as noise removal, correlated double sampling (CDS) is performed as the signal processing.

The horizontal driving unit 24 is constituted by a shift register, an address decoder, or the like. The horizontal driving unit 24 selects, in order, unit circuits corresponding to the pixel columns of the column signal processing unit 23. The selection and scanning of the horizontal driving unit 24 cause the pixel signals resulting from the signal processing in the column signal processing unit 23 to be output to the output unit 25 through a horizontal signal line 51.

The output unit 25 subjects the pixel signals sequentially input from the respective parts of the column signal processing unit 23 through the horizontal signal line 51 to predetermined signal processing. The output unit 25 outputs resulting signals.

The control unit 26 is constituted by a timing generator or the like that generates various kinds of timing signals. The control unit 26 performs driving control of the vertical driving unit 22, the column signal processing unit 23, the horizontal driving unit 24, and the like, on the basis of the various kinds of timing signals generated by the timing generator.

Incidentally, in the following description, for the convenience of the description, a distinction is made by describing the pixels arranged two-dimensionally in the pixel array unit 21 in the first embodiment as pixels 100, and describing pixels arranged two-dimensionally in the pixel array unit 21 in a second embodiment as pixels 200.

### 1. First Embodiment

Description will be made of a structure including the pixels 100 arranged two-dimensionally in the pixel array unit 21 in the solid-state imaging device 10.

### First Example

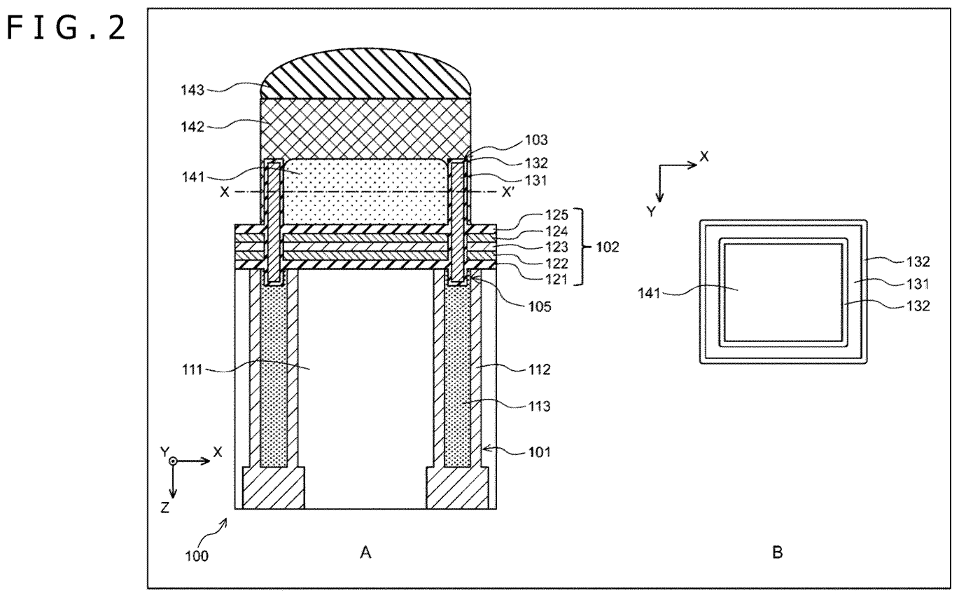

FIG. 2 is a diagram illustrating a first example of a structure including a pixel 100. A in FIG. 2 represents a sectional structure. B in FIG. 2 represents a plan view when the sectional structure in A in FIG. 2 is cut by a plane X-X′ indicated by alternate long and short dashed lines in the figure. In the following description, in the sectional structure, a structure in an upward-downward direction (Z-direction) in the figure will be referred to also as a vertical structure, and a structure in a left-right direction (X-direction) in the figure will be referred to also as a horizontal structure.

In A in FIG. 2, the pixel 100 has a photoelectric conversion region 111. The photoelectric conversion region 111, for example, includes a semiconductor region of a second conductivity type in a well region of a first conductivity type which well region is formed in a silicon substrate. A p-type can be set as the first conductivity type, and an n-type can be set as the second conductivity type.

The photoelectric conversion region 111 is electrically and optically isolated by an element isolation region 101 as a pixel isolation region. The element isolation region 101 is formed so as to surround the photoelectric conversion region 111. The element isolation region 101 includes an element isolation structure as an FFTI (Front Full Trench Isolation). The element isolation region 101 has a structure including a first region 112 and a second region 113 formed in a groove (trench). Silicon oxide (SiO₂), for example, is used as a material for the first region 112. Polysilicon (Poly-Si), for example, is used as a material for the second region 113.

An antireflection film 102 is formed on an upper surface of the silicon substrate in which the photoelectric conversion region 111 is formed. The antireflection film 102 is formed by laminating a first layer 121 to a fifth layer 125.

Aluminum oxide (AlOx) is used as a material for the first layer 121. Hafnium oxide (HfOx), for example, is used as a material for the second layer 122. Silicon oxide (SiO₂), for example, is used as a material for the third layer 123. Hafnium oxide (HfOx), for example, is used as a material for the fourth layer 124. Aluminum oxide (AlOx), for example, is used as a material for the fifth layer 125. It is to be noted that the number of layers of the antireflection film 102 is not limited to five, and may be another number of layers.

A color filter 141 is formed on an upper surface of the antireflection film 102. A structural body 103 having a structure including a low refractive index film 131 and a high refractive index film 132 is formed on the side surfaces of the color filter 141. The structural body 103 is formed so as to surround the color filter 141. The structural body 103 can function as an inter-pixel light shielding film. In the structural body 103, the high refractive index film 132 is formed so as to wrap (so as to cover) the whole of the low refractive index film 131.

The low refractive index film 131 is formed by a material having a lower refractive index than the high refractive index film 132. The high refractive index film 132 is formed by a material having a higher refractive index than that of the low refractive index film 131. For example, aluminum oxide (AlOx) can be used as a material for the high refractive index film 132, and a material having a lower refractive index than aluminum oxide (AlOx) can be used as a material for the low refractive index film 131. A difference between the refractive index of the low refractive index film 131 and the refractive index of the high refractive index film 132 is preferably large.

The vertical structure of the structural body 103 is a structure formed not only on the side surfaces of the color filter 141 but also in a groove 105 that penetrates the antireflection film 102 and reaches an upper portion of the element isolation region 101. The structural body 103 penetrates to a top surface of the silicon substrate, and is in contact with the second region 113 of the element isolation region 101. When the structural body 103 is thus formed so as to penetrate the antireflection film 102, a color mixture can be suppressed. On the other hand, the horizontal structure of the structural body 103 is a structure such that a width thereof is narrower and thinner than a width of the second region 113 of the element isolation region 101.

As illustrated in the plan view of B in FIG. 2, the structural body 103 has a structure such that the low refractive index film 131 covered in entirety by the high refractive index film 132 surrounds the color filter 141. Each of the pixels formed in the silicon substrate has a similar structure. That is, structural bodies 103 formed for the respective pixels arranged two-dimensionally in the pixel array unit 21 are arranged in a lattice manner, and are formed as a grid structure. In other words, the structural bodies 103 can also be said to be grid structural bodies.

A color filter corresponding to a wavelength of red (R), green (G), or blue (B), for example, can be used as the color filter 141. In addition, color filters corresponding to a Bayer array can be used as color filters 141 formed in the respective pixels arranged two-dimensionally in the pixel array unit 21. A planarizing film 142 and an on-chip microlens 143 are laminated on an upper surface of the color filter 141.

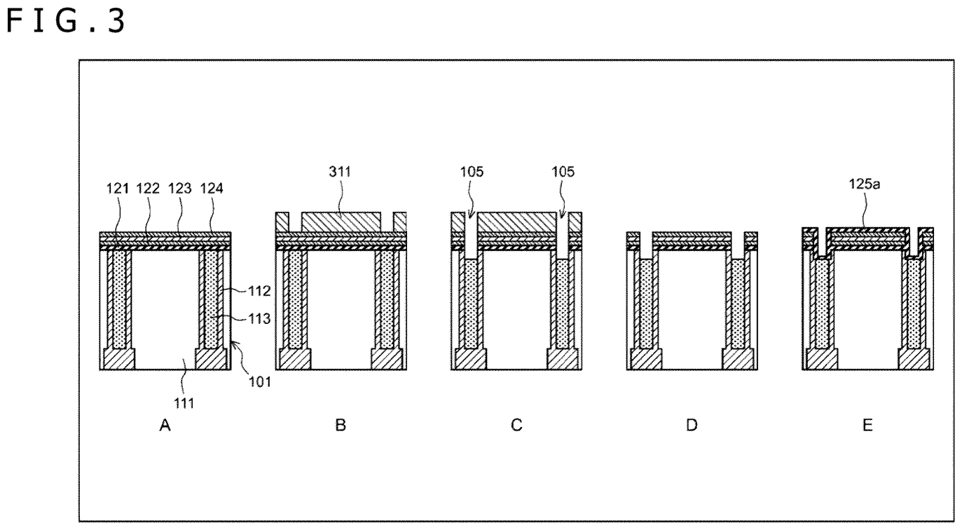

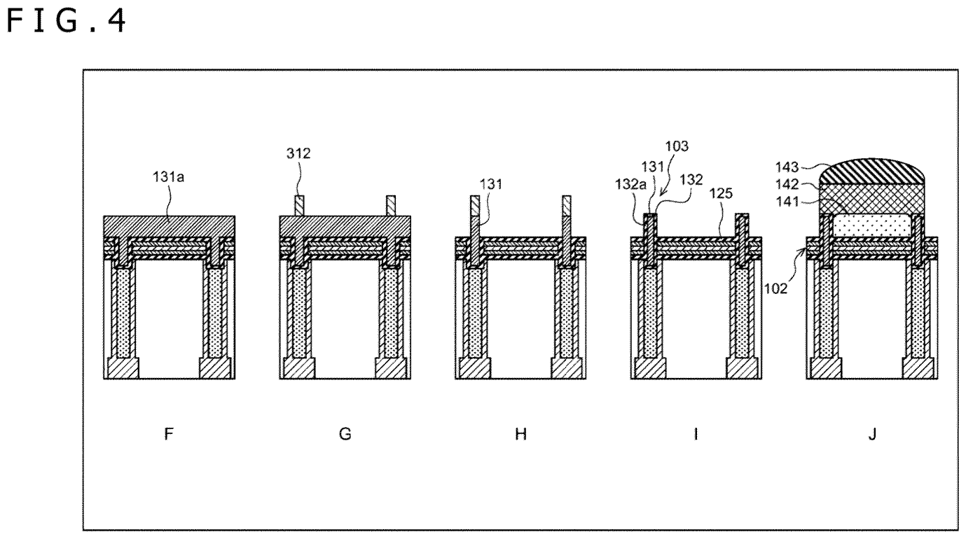

FIG. 3 and FIG. 4 are diagrams illustrating an example of a manufacturing method including processes for forming the structure illustrated in FIG. 2. In this manufacturing method, processes after the photoelectric conversion region 111 and the element isolation region 101 are formed in the silicon substrate are illustrated in process order. The same is true for the description of the following manufacturing methods.

First, in a process illustrated in A of FIG. 3, four layers as the first layer 121 to fourth layer 124 in a laminated state are formed on the upper surface of the silicon substrate in which the photoelectric conversion region 111 and the element isolation region 101 are formed. In a process illustrated in B in FIG. 3, a processing mask 311 having a predetermined pattern is formed on the four laminated layers.

In a process illustrated in C in FIG. 3, an unnecessary part is removed by processing the part corresponding to the pattern of the processing mask 311. The groove 105 is thereby formed. The groove 105 penetrates the first layer 121 to fourth layer 124, and a bottom surface of the groove 105 reaches an upper portion of the element isolation region 101. In a process illustrated in D in FIG. 3, the processing mask 311 is peeled off.

In a process illustrated in E in FIG. 3, a film 125a including aluminum oxide (AlOx) or the like as a material for the fifth layer 125 and the high refractive index film 132 is formed on the four laminated layers by using an atomic layer deposition method (ALD) or the like. The film 125a is formed also within the groove 105 (side surfaces and bottom surface of the groove 105). Next, in a process illustrated in F in FIG. 4, a film 131a including a material for the low refractive index film 131 is formed so as to fill the groove 105 on the film 125a.

In a process illustrated in G in FIG. 4, a processing mask 312 is formed on the film 131a. In a process illustrated in H in FIG. 4, an unnecessary part is removed by processing the part corresponding to the pattern of the processing mask 312. The low refractive index film 131 is thereby formed. The processing mask 312 is peeled off. Next, in a process illustrated in I in FIG. 4, a film 132a including aluminum oxide (AlOx) or the like as a material for the high refractive index film 132 is formed on a part of the low refractive index film 131 which part juts in a shape of a projection by using the atomic layer deposition method (ALD) or the like.

The high refractive index film 132 is thereby formed so as to wrap the whole of the low refractive index film 131. The structural body 103 is consequently formed. In addition, the antireflection film 102 in which the first layer 121 to fifth layer 125 are laminated is formed. In a subsequent process, the color filter 141, the planarizing film 142, and the on-chip microlens 143 are laminated onto the antireflection film 102 in order (J in FIG. 4). The structure illustrated in FIG. 2 can be formed by undergoing such processes.

Because the structure as described above is provided, the high refractive index film 132 has such a structure as to cover the whole of the low refractive index film 131 in the structural body 103. It is therefore possible to reflect light with a higher reflecting effect due to a difference between the refractive index of the material of the low refractive index film 131 and the refractive index of the material of the high refractive index film 132. In addition, because the whole of the low refractive index film 131 is covered by the high refractive index film 132, a protecting effect is provided. Further, because the structural body 103 is formed so as to penetrate the antireflection film 102, a color mixture can be suppressed.

### Second Example

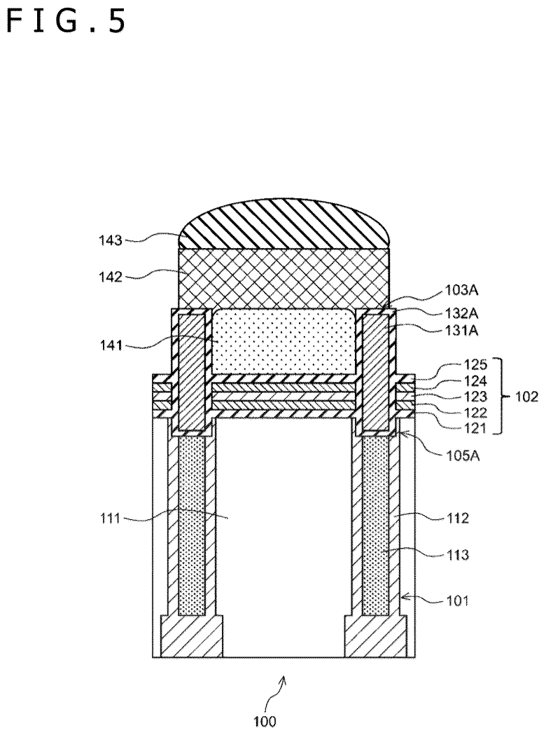

FIG. 5 is a diagram illustrating a second example of the structure including the pixel 100. In FIG. 5, parts corresponding to those in FIG. 2 are identified by the same reference signs, and description thereof will be omitted as appropriate. Incidentally, description of parts having the same reference signs also in the subsequent drawings will be omitted as appropriate.

In the structure illustrated in FIG. 5, as compared with the structure illustrated in FIG. 2, a structural body 103A is formed in place of the structural body 103.

The structural body 103A includes a low refractive index film 131A and a high refractive index film 132A formed so as to wrap the whole of the low refractive index film 131A. For example, aluminum oxide (AlOx) can be used as a material for the high refractive index film 132A, and a material having a lower refractive index than aluminum oxide (AlOx) can be used as a material for the low refractive index film 131A.

As in the structural body 103 (FIG. 2), the vertical structure of the structural body 103A is a structure formed on the side surfaces of the color filter 141 and also within a groove 105A. As with the groove 105 (FIG. 2), the groove 105A penetrates the antireflection film 102, and reaches an upper portion of the element isolation region 101.

On the other hand, the horizontal structure of the structural body 103A is a structure such that the width of the groove 105A is wider than the width of the groove 105 (FIG. 2) and such that the width of the groove 105A is consequently wider and thicker than the width of the second region 113 of the element isolation region 101. That is, the width of the structural body 103A is equal to or less than the width of the element isolation region 101 including an element isolation structure as an FFTI, and is equal to or more than the width of the second region 113 formed by polysilicon (Poly-Si) or the like.

As described above, whereas the width of the structural body 103 is equal to or less than the width of the second region 113 of the element isolation region 101 in the structure illustrated in FIG. 2, the width of the structural body 103A is equal to or less than the width of the element isolation region 101 and is equal to or more than the width of the second region 113 in the structure illustrated in FIG. 5. Thus, the structural body 103 can be formed with an optimum width (thickness) in the pixel 100.

Incidentally, a manufacturing method including processes for forming the structure illustrated in FIG. 5 is similar to the manufacturing method of FIG. 3 and FIG. 4 described above, and therefore description thereof will be omitted.

### Third Example

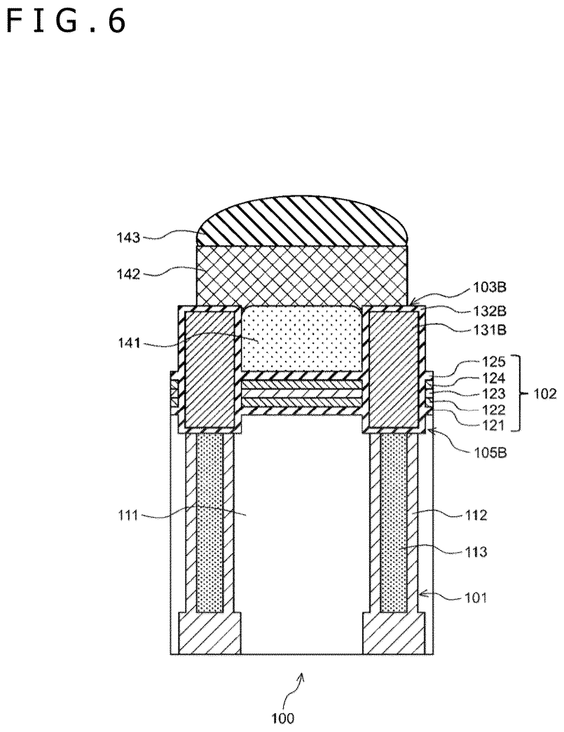

FIG. 6 is a diagram illustrating a third example of the structure including the pixel 100.

In the structure illustrated in FIG. 6, as compared with the structure illustrated in FIG. 2, a structural body 103B is formed in place of the structural body 103.

The structural body 103B includes a low refractive index film 131B and a high refractive index film 132B formed so as to wrap the whole of the low refractive index film 131B. The high refractive index film 132B is formed by a material having a higher refractive index than that of the low refractive index film 131B (material such as aluminum oxide (AlOx)).

As in the structural body 103 (FIG. 2), the vertical structure of the structural body 103B is a structure formed on the side surfaces of the color filter 141 and also within a groove 105B. As with the groove 105 (FIG. 2), the groove 105B penetrates the antireflection film 102, and reaches an upper portion of the element isolation region 101.

On the other hand, the horizontal structure of the structural body 103B is a structure such that the width of the groove 105B is even wider than the width of the groove 105A (FIG. 5) and such that the width of the groove 105B is consequently wider and thicker than the width of the element isolation region 101. That is, the width of the structural body 103B is equal to or more than the width of the element isolation region 101 including an element isolation structure as an FFTI.

As described above, whereas the width of the structural body 103 is equal to or less than the width of the second region 113 of the element isolation region 101 in the structure illustrated in FIG. 2, the width of the structural body 103B is equal to or more than the width of the element isolation region 101 in the structure illustrated in FIG. 6. Thus, the structural body 103 can be formed in an optimum shape for the pixel 100.

Incidentally, a manufacturing method including processes for forming the structure illustrated in FIG. 6 is similar to the manufacturing method of FIG. 3 and FIG. 4 described above, and therefore description thereof will be omitted.

### Fourth Example

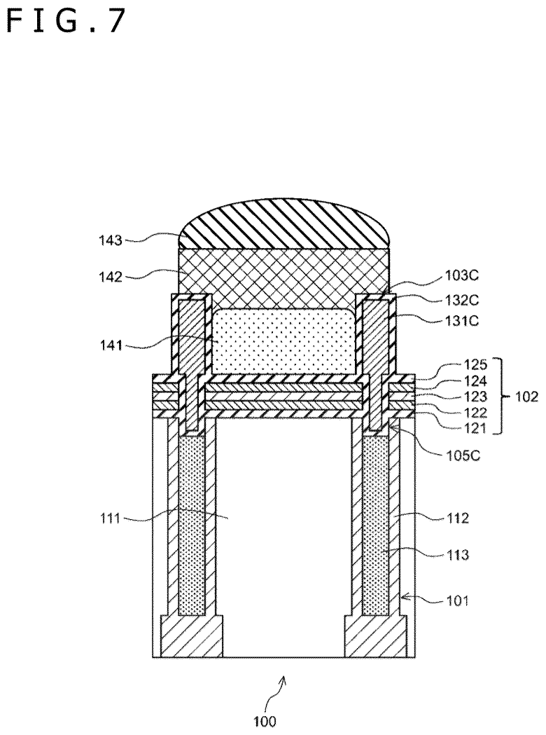

FIG. 7 is a diagram illustrating a fourth example of the structure including the pixel 100.

In the structure illustrated in FIG. 7, as compared with the structure illustrated in FIG. 2, a structural body 103C is formed in place of the structural body 103.

The structural body 103C includes a low refractive index film 131C and a high refractive index film 132C formed so as to wrap the whole of the low refractive index film 131C. The high refractive index film 132C is formed by a material having a higher refractive index than that of the low refractive index film 131C (material such as aluminum oxide (AlOx)).

The vertical structure of the structural body 103C is a structure formed on the side surfaces of the color filter 141 and also within a groove 105C. As with the groove 105 (FIG. 2), the groove 105C penetrates the antireflection film 102, and reaches an upper portion of the element isolation region 101.

On the other hand, the horizontal structure of the structural body 103C is a two-stage structure in which an upper portion thereof as a part upward of the upper surface of the antireflection film 102 and a lower portion thereof as a part within the groove 105C penetrating the antireflection film 102 are different in width from each other. That is, the structural body 103C has a structure such that the width of the upper portion is wider and thicker than the width of the lower portion.

As described above, whereas the width of the structural body 103 is uniform in the structure illustrated in FIG. 2, the width of the structural body 103C is not uniform and the width of the upper portion is wider than the width of the lower portion in the structure illustrated in FIG. 7. Such a structure makes it possible to cope with miniaturization of the element isolation region 101 including an element isolation structure as an FFTI in the pixel 100.

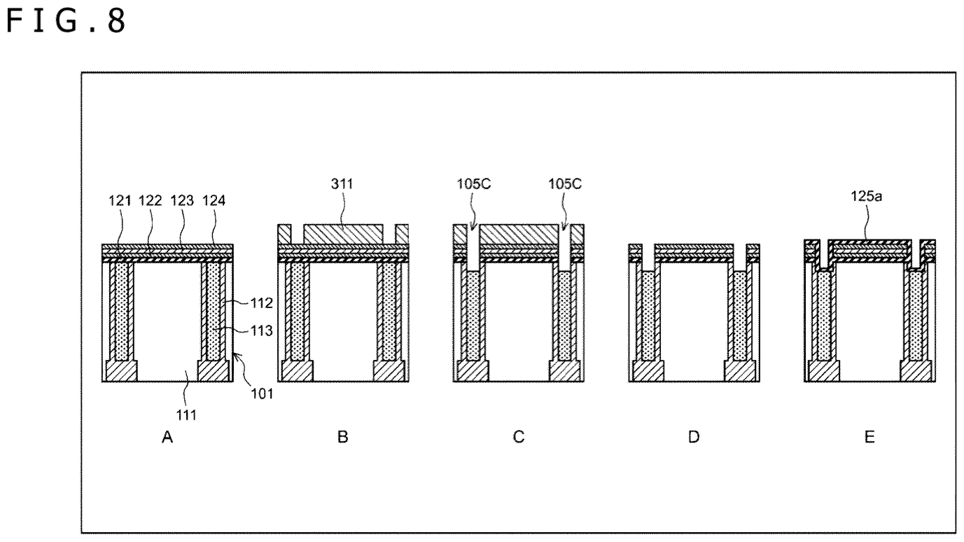

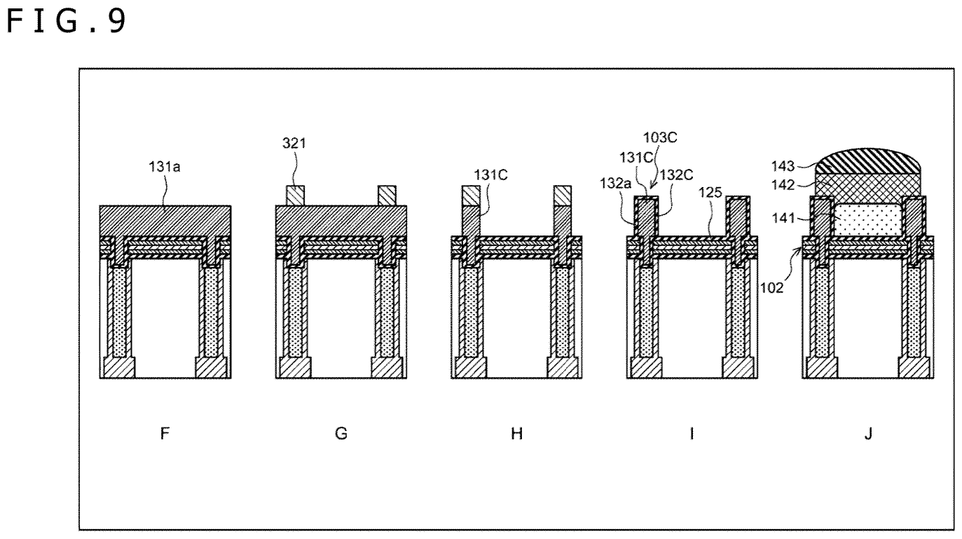

FIG. 8 and FIG. 9 are diagrams illustrating an example of a manufacturing method including processes for forming the structure illustrated in FIG. 7.

In processes illustrated in A to E in FIG. 8, as in the processes illustrated in A to E in FIG. 3, the groove 105C is formed by processing a part corresponding to the pattern of the processing mask 311, and thereafter the film 125a including a material such as aluminum oxide (AlOx) is formed by using the atomic layer deposition method (ALD) or the like.

Thereafter, in processes illustrated in F and G in FIG. 9, as in the processes illustrated in F and G in FIG. 4, the film 131a including a material having a lower refractive index than aluminum oxide (AlOx) or the like is formed, and further a processing mask 321 is formed on the film 131a. Here, the processing mask 321 is different in pattern from the processing mask 312 (FIG. 4), and has a shape for making the width of the upper portion of the structural body 103C wider than the width of the lower portion thereof.

In a process illustrated in H in FIG. 9, the low refractive index film 131C is formed by processing a part corresponding to the pattern of the processing mask 321. The width of the upper portion of the thus formed low refractive index film 131C is wider than the width of the lower portion thereof. The processing mask 321 is peeled off.

Next, in a process illustrated in I in FIG. 9, the film 132a including aluminum oxide (AlOx) or the like is formed on an upper portion (part jutting in a shape of a projection) of the low refractive index film 131C by using the atomic layer deposition method (ALD) or the like. The high refractive index film 132C is thereby formed so as to wrap the whole of the low refractive index film 131C. The structural body 103C is consequently formed. In addition, the antireflection film 102 in which the first layer 121 to fifth layer 125 are laminated is formed.

In a subsequent process, the color filter 141, the planarizing film 142, and the on-chip microlens 143 are laminated onto the antireflection film 102 in order (J in FIG. 9). The structure illustrated in FIG. 7 can be formed by undergoing such processes.

### Fifth Example

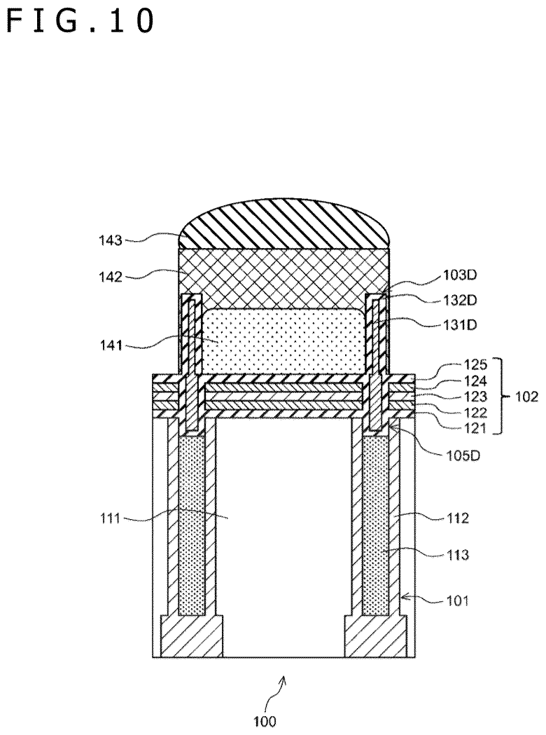

FIG. 10 is a diagram illustrating a fifth example of the structure including the pixel 100.

In the structure illustrated in FIG. 10, as compared with the structure illustrated in FIG. 2, a structural body 103D is formed in place of the structural body 103.

The structural body 103D includes a low refractive index film 131D and a high refractive index film 132D formed so as to wrap the whole of the low refractive index film 131D. The high refractive index film 132D is formed by a material having a higher refractive index than that of the low refractive index film 131D (material such as aluminum oxide (AlOx)).

The vertical structure of the structural body 103D is a structure formed on the side surfaces of the color filter 141 and also within a groove 105D. As with the groove 105 (FIG. 2), the groove 105D penetrates the antireflection film 102, and reaches an upper portion of the element isolation region 101.

On the other hand, the horizontal structure of the structural body 103D is a two-stage structure in which the width of an upper portion thereof and the width of a lower portion thereof are different from each other. That is, the structural body 103D has a structure in which the width of the upper portion is narrower and thinner than the width of the lower portion.

As described above, whereas the width of the structural body 103 is uniform in the structure illustrated in FIG. 2, the width of the structural body 103D is not uniform and the width of the upper portion is narrower than the width of the lower portion in the structure illustrated in FIG. 10. Such a structure makes it possible to increase the opening area of the photoelectric conversion region 111 and thus improve sensitivity in the pixel 100.

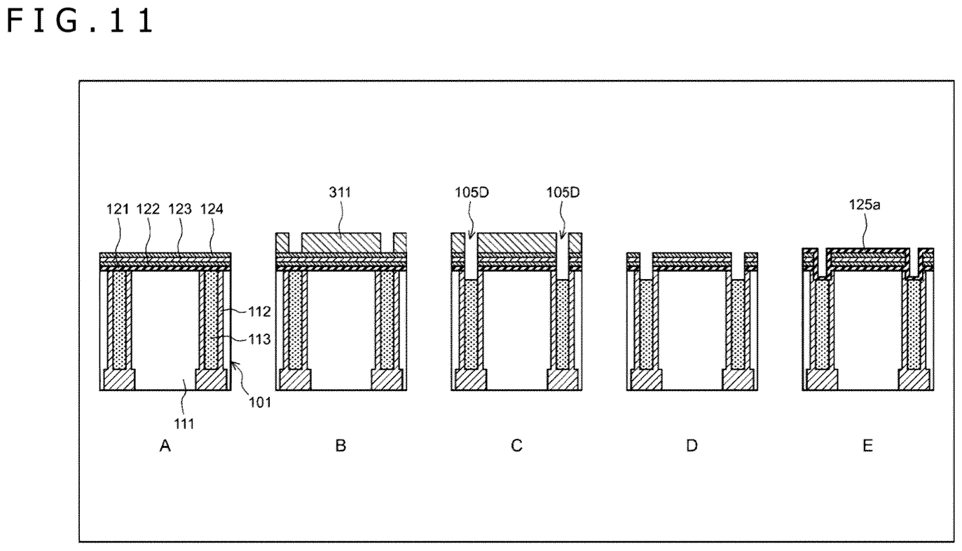

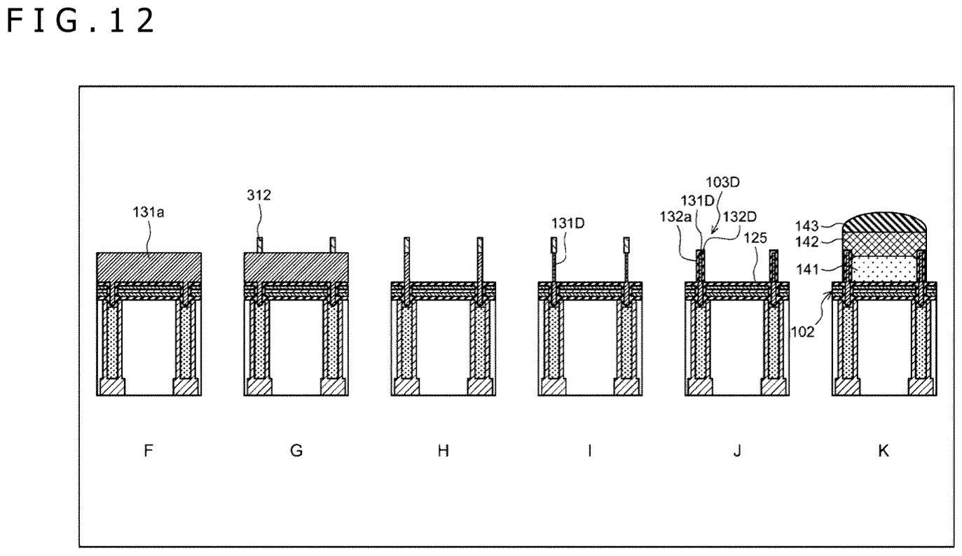

FIG. 11 and FIG. 12 are diagrams illustrating an example of a manufacturing method including processes for forming the structure illustrated in FIG. 10.

In processes illustrated in A to E in FIG. 11, as in the processes illustrated in A to E in FIG. 3, the groove 105D is formed by processing a part corresponding to the pattern of the processing mask 311, and thereafter the film 125a is formed.

Thereafter, in processes illustrated in F and G in FIG. 12, as in the processes illustrated in F and G in FIG. 4, the film 131a is formed, and further the processing mask 312 is formed on the film 131a. In processes illustrated in H and I in FIG. 12, an unnecessary part is removed by processing the part corresponding to the pattern of the processing mask 312, and thereafter processing of thinning the film 131a, from which the unnecessary part is removed, by slimming is performed. The low refractive index film 131D is thereby formed (I in FIG. 12). The width of the upper portion of the thus formed low refractive index film 131D is narrower than the width of the lower portion thereof. The processing mask 312 is peeled off.

Next, in a process illustrated in J in FIG. 12, as in the process illustrated in I in FIG. 4, the film 132a is formed on an upper portion (part jutting in a shape of a projection) of the low refractive index film 131D. The high refractive index film 132D is thereby formed so as to wrap the whole of the low refractive index film 131D. The structural body 103D is consequently formed. In addition, the antireflection film 102 in which the first layer 121 to fifth layer 125 are laminated is formed.

In a subsequent process, the color filter 141, the planarizing film 142, and the on-chip microlens 143 are laminated onto the antireflection film 102 in order (K in FIG. 12). The structure illustrated in FIG. 10 can be formed by undergoing such processes.

### Sixth Example

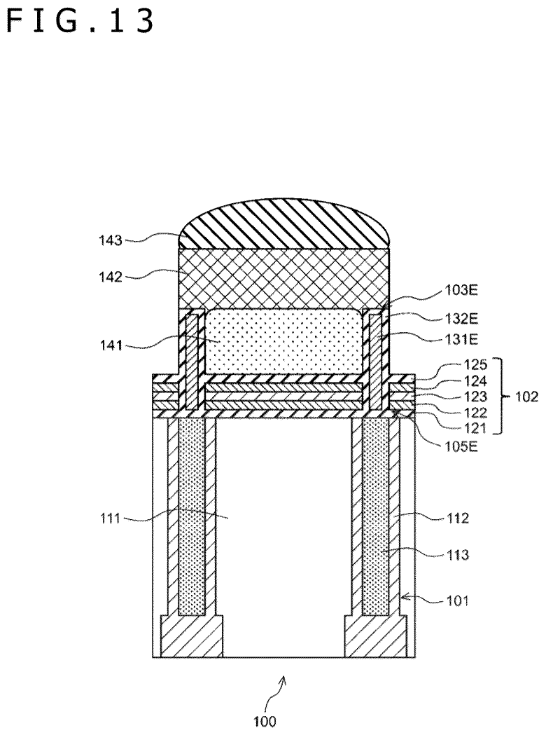

FIG. 13 is a diagram illustrating a sixth example of the structure including the pixel 100.

In the structure illustrated in FIG. 13, as compared with the structure illustrated in FIG. 2, a structural body 103E is formed in place of the structural body 103.

The structural body 103E includes a low refractive index film 131E and a high refractive index film 132E formed so as to wrap the whole of the low refractive index film 131E. The high refractive index film 132E is formed by a material having a higher refractive index than that of the low refractive index film 131E (material such as aluminum oxide (AlOx)).

The vertical structure of the structural body 103E is a structure formed on the side surfaces of the color filter 141 and also within a groove 105E. The groove 105E has a structure such that the groove 105E does not reach an upper portion of the element isolation region 101 (top surface of the silicon substrate), and such that the first layer 121 of the antireflection film 102 which first layer is formed at the bottom surface of the groove 105E is integral with the high refractive index film 132E.

In the structure illustrated in FIG. 2, the structural body 103 penetrates the antireflection film 102, and reaches the second region 113 of the element isolation region 101. However, in the structure illustrated in FIG. 13, the structural body 103E is not in contact with the second region 113 including polysilicon (Poly-Si) or the like. When such a structure is formed, the structural body 103 is not in contact with polysilicon (Poly-Si) or the like, and overetching control is unnecessary at a time of manufacturing. There is thus an advantage of facilitating processing.

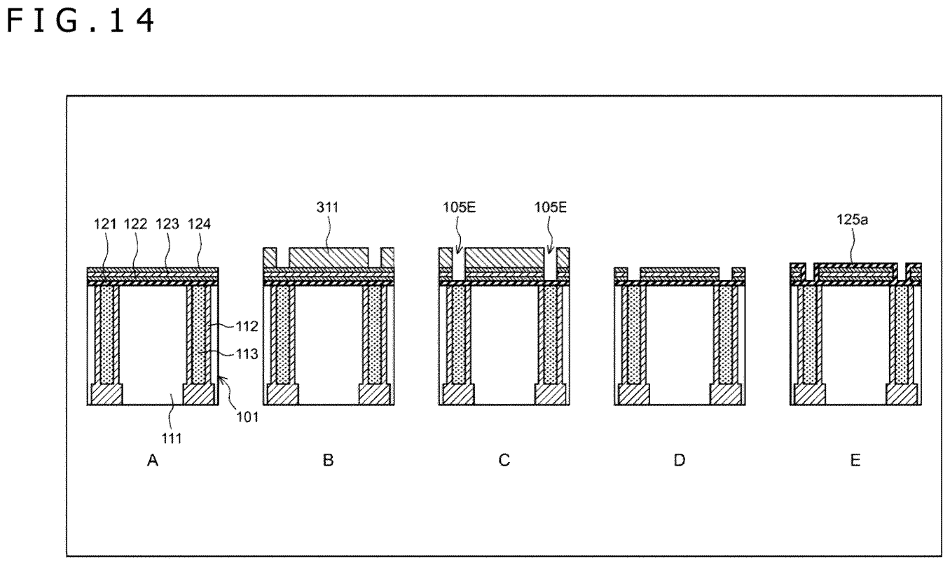

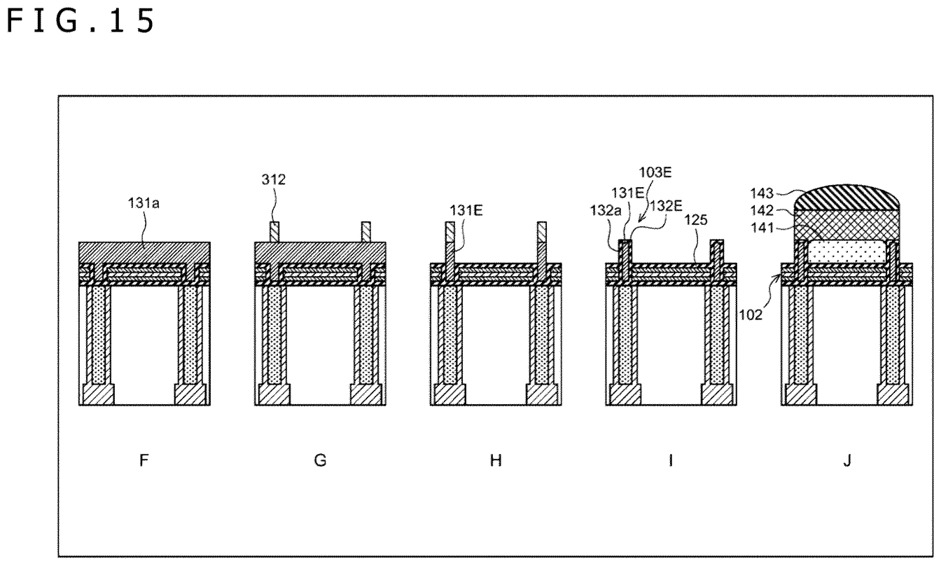

FIG. 14 and FIG. 15 are diagrams illustrating an example of a manufacturing method including processes for forming the structure illustrated in FIG. 13.

In processes illustrated in A to E in FIG. 14, as in the processes illustrated in A to E in FIG. 3, the groove 105E is formed by processing a part corresponding to the pattern of the processing mask 311. However, the groove 105E is different in that the depth of the groove 105E is shallower than that of the groove 105 (C and D in FIG. 3). That is, in the processes illustrated in C and D in FIG. 14, unlike the processes illustrated in C and D in FIG. 3, the groove 105E is formed which penetrates three layers, that is, the second layer 122 to fourth layer 124 among the four layers forming the antireflection film 102. Then, the film 125a is formed on the fourth layer 124 and on the side surfaces of the groove 105E.

In processes illustrated in F to J in FIG. 15, as in the processes illustrated in F to J in FIG. 4, the low refractive index film 131E is formed by forming the film 131a and thereafter processing a part corresponding to the pattern of the processing mask 312 (H in FIG. 15). Next, the processing mask 312 is peeled off. Thereafter, in a process illustrated in I in FIG. 15, the film 132a is formed on an upper portion (part jutting in a shape of a projection) of the low refractive index film 131E.

The high refractive index film 132E is thereby formed so as to wrap the whole of the low refractive index film 131E. The structural body 103E is consequently formed. In addition, the antireflection film 102 in which the first layer 121 to fifth layer 125 are laminated is formed. The structural body 103E penetrates the antireflection film 102 and does not reach an upper portion of the element isolation region 101 (is stopped in the antireflection film 102, as it were).

In a subsequent process, the color filter 141, the planarizing film 142, and the on-chip microlens 143 are laminated onto the antireflection film 102 in order (J in FIG. 15). The structure illustrated in FIG. 13 can be formed by undergoing such processes.

### Seventh Example

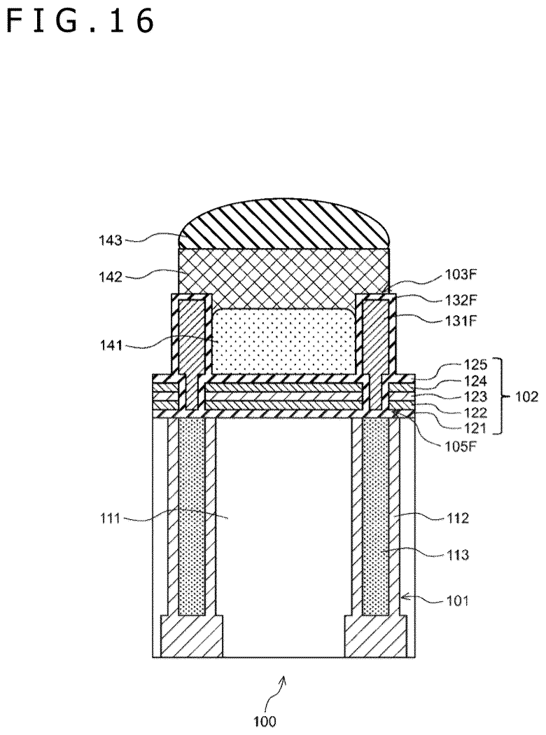

FIG. 16 is a diagram illustrating a seventh example of the structure including the pixel 100.

In the structure illustrated in FIG. 16, as compared with the structure illustrated in FIG. 13, a structural body 103F is formed in place of the structural body 103E.

The structural body 103F includes a low refractive index film 131F and a high refractive index film 132F formed so as to wrap the whole of the low refractive index film 131F. The high refractive index film 132F is formed by a material having a higher refractive index than that of the low refractive index film 131F (material such as aluminum oxide (AlOx)).

The vertical structure of the structural body 103F is a structure formed on the side surfaces of the color filter 141 and also within a groove 105F. As with the groove 105E (FIG. 13), the groove 105F has a structure such that the groove 105F does not reach an upper portion of the element isolation region 101, and such that the first layer 121 of the antireflection film 102 which first layer is formed at the bottom surface of the groove 105F is integral with the high refractive index film 132F.

On the other hand, the horizontal structure of the structural body 103F is a two-stage structure in which an upper portion thereof as a part upward of the upper surface of the antireflection film 102 and a lower portion thereof as a part within the groove 105F penetrating the antireflection film 102 are different in width from each other. That is, the structural body 103F has a structure such that the width of the upper portion is wider and thicker than the width of the lower portion.

As described above, whereas the width of the structural body 103E is uniform in the structure illustrated in FIG. 13, the width of the structural body 103F is not uniform and the width of the upper portion is wider than the width of the lower portion in the structure illustrated in FIG. 16. When such a structure is formed, the structural body 103 is not in contact with the second region 113 of polysilicon (Poly-Si) or the like, and overetching control is unnecessary at a time of manufacturing. There is thus an advantage of facilitating processing. In addition, the structural body 103 can be formed in an optimum shape for the pixel 100.

### Eighth Example

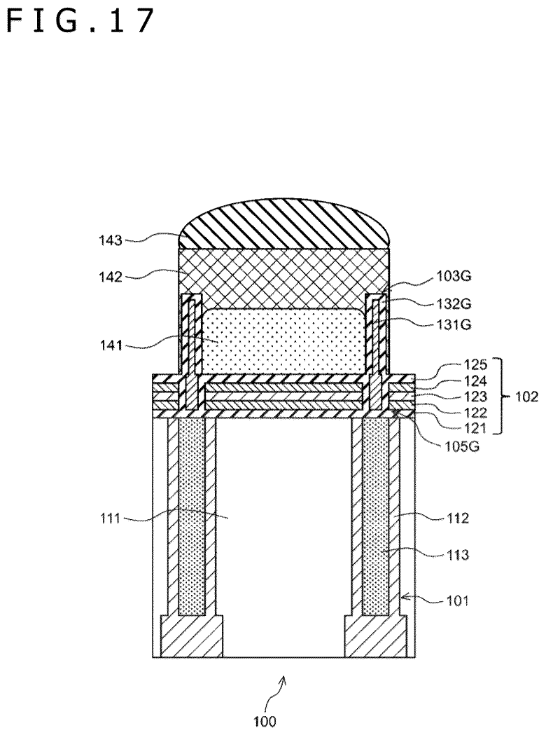

FIG. 17 is a diagram illustrating an eighth example of the structure including the pixel 100.

In the structure illustrated in FIG. 17, as compared with the structure illustrated in FIG. 13, a structural body 103G is formed in place of the structural body 103E.

The structural body 103G includes a low refractive index film 131G and a high refractive index film 132G formed so as to wrap the whole of the low refractive index film 131G. The high refractive index film 132G is formed by a material having a higher refractive index than that of the low refractive index film 131G (material such as aluminum oxide (AlOx)).

The vertical structure of the structural body 103G is a structure formed on the side surfaces of the color filter 141 and also within a groove 105G. As with the groove 105E (FIG. 13), the groove 105G has a structure such that the groove 105G does not reach an upper portion of the element isolation region 101, and such that the first layer 121 of the antireflection film 102 which first layer is formed at the bottom surface of the groove 105G is integral with the high refractive index film 132G.

On the other hand, the horizontal structure of the structural body 103G is a two-stage structure in which the width of an upper portion thereof and the width of a lower portion thereof are different from each other. That is, the structural body 103G has a structure in which the width of the upper portion is narrower and thinner than the width of the lower portion.

As described above, whereas the width of the structural body 103E is uniform in the structure illustrated in FIG. 13, the width of the structural body 103G is not uniform and the width of the upper portion is narrower than the width of the lower portion in the structure illustrated in FIG. 17. When such a structure is formed, the structural body 103 is not in contact with the second region 113 of polysilicon (Poly-Si) or the like, and overetching control is unnecessary at a time of manufacturing. There is thus an advantage of facilitating processing. In addition, it is possible to increase the opening area of the photoelectric conversion region 111 and thus improve sensitivity in the pixel 100.

### Ninth Example

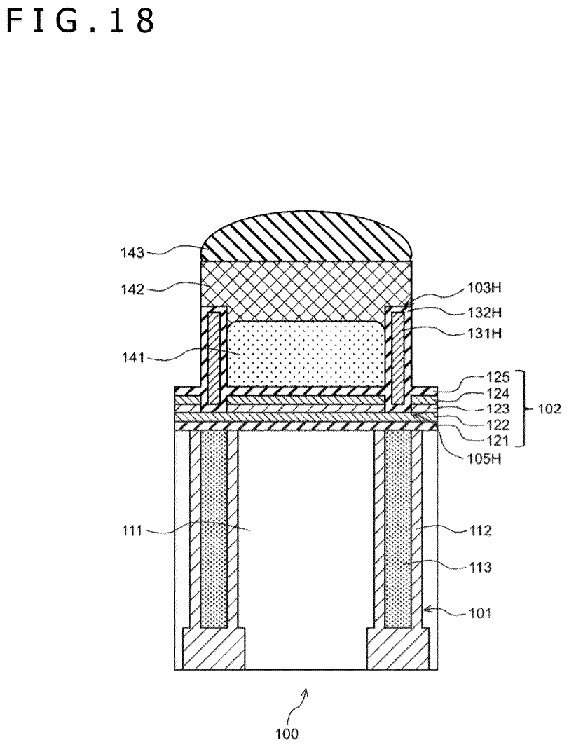

FIG. 18 is a diagram illustrating a ninth example of the structure including the pixel 100.

In the structure illustrated in FIG. 18, as compared with the structure illustrated in FIG. 2, a structural body 103H is formed in place of the structural body 103.

The structural body 103H includes a low refractive index film 131H and a high refractive index film 132H formed so as to wrap the whole of the low refractive index film 131H. The high refractive index film 132H is formed by a material having a higher refractive index than that of the low refractive index film 131H (material such as aluminum oxide (AlOx)).

The vertical structure of the structural body 103H is a structure formed on the side surfaces of the color filter 141 and also within a groove 105H. The groove 105H has a structure such that the groove 105H penetrates only three layers on an upper side, that is, the third layer 123 to fifth layer 125 among the five layers of the antireflection film 102, and such that a lower surface of the structural body 103H is in contact with the upper surface of the second layer 122 (is stopped at the second layer 122 of the antireflection film 102, as it were).

In the structure illustrated in FIG. 2, the structural body 103 penetrates all of the layers of the antireflection film 102, and reaches the second region 113 of the element isolation region 101. However, in the structure illustrated in FIG. 18, the structural body 103H penetrates only the three layers on the upper side of the antireflection film 102, and is stopped at the second layer 122 including hafnium oxide (HfOx) or the like. Color mixture performance can be improved by digging the groove 105H and embedding the structural body 103H. When hafnium oxide (HfOx) having a characteristic of being difficult to etch is used as a material for the second layer 122, the hafnium oxide (HfOx) can be used as a stopper film at a time of manufacturing. The manufacturing is facilitated by thus using the second layer 122 as an etching stopper.

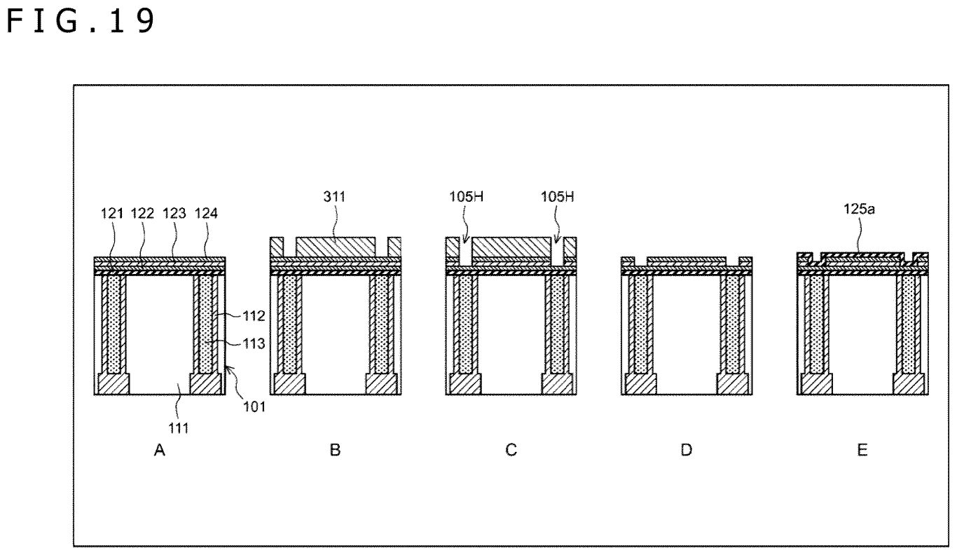

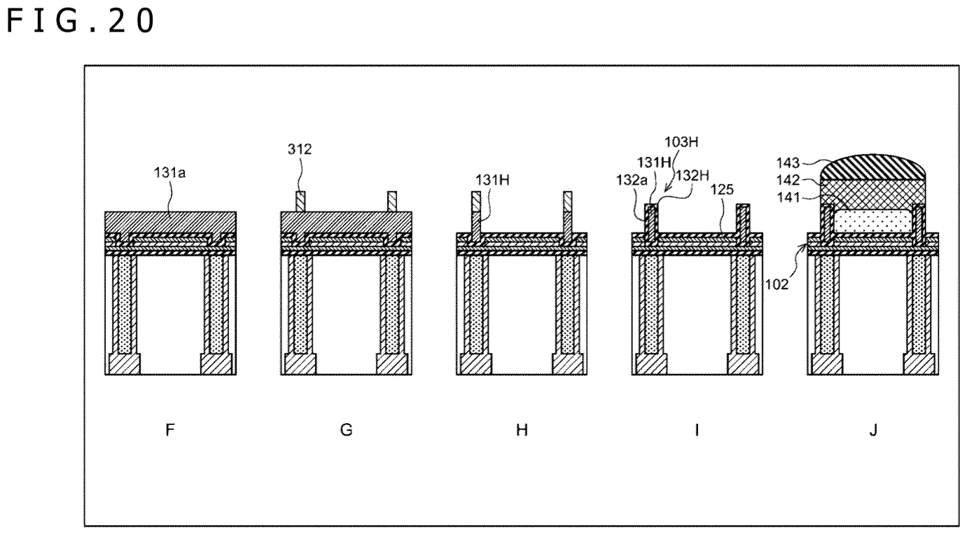

FIG. 19 and FIG. 20 are diagrams illustrating an example of a manufacturing method including processes for forming the structure illustrated in FIG. 18.

In processes illustrated in A to E in FIG. 19, as in the processes illustrated in A to E in FIG. 3, the groove 105H is formed by processing a part corresponding to the pattern of the processing mask 311. However, the groove 105H is different in that the depth of the groove 105H is shallower than that of the groove 105 (C and D in FIG. 3). That is, in the processes illustrated in C and D in FIG. 19, unlike the processes illustrated in C and D in FIG. 3, the groove 105H is formed which penetrates two layers, that is, the third layer 123 and the fourth layer 124 among the four layers forming the antireflection film 102. Then, the film 125a is formed on the fourth layer 124 and within the groove 105H (side surfaces and bottom surface of the groove 105H).

In processes illustrated in F to J in FIG. 20, as in the processes illustrated in F to J in FIG. 4, the low refractive index film 131H is formed by forming the film 131a and thereafter processing a part corresponding to the pattern of the processing mask 312 (H in FIG. 20). Next, the processing mask 312 is peeled off. Thereafter, in a process illustrated in I in FIG. 20, the film 132a is formed on an upper portion (part jutting in a shape of a projection) of the low refractive index film 131H.

The high refractive index film 132H is thereby formed so as to wrap the whole of the low refractive index film 131H. The structural body 103H is consequently formed. In addition, the antireflection film 102 in which the first layer 121 to fifth layer 125 are laminated is formed. The structural body 103H penetrates the three layers on the upper side of the antireflection film 102, but is stopped at the second layer 122 including hafnium oxide (HfOx) or the like.

In a subsequent process, the color filter 141, the planarizing film 142, and the on-chip microlens 143 are laminated onto the antireflection film 102 in order (J in FIG. 20). The structure illustrated in FIG. 18 can be thereby formed.

### Tenth Example

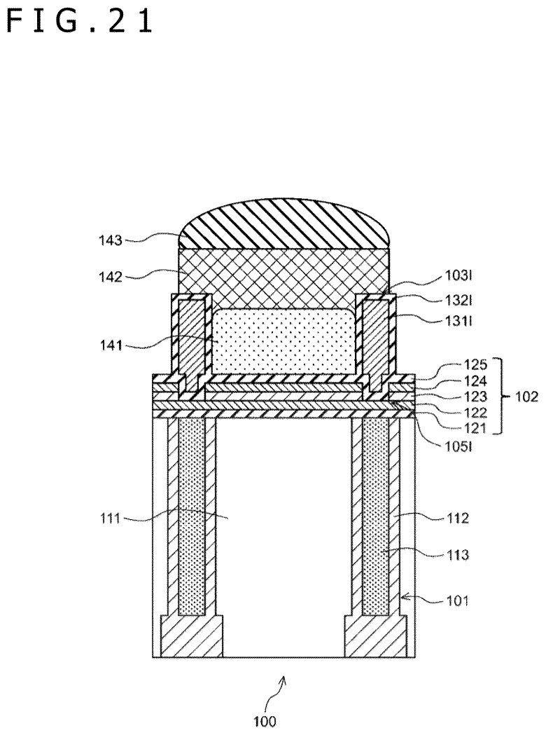

FIG. 21 is a diagram illustrating a tenth example of the structure including the pixel 100.

In the structure illustrated in FIG. 21, as compared with the structure illustrated in FIG. 18, a structural body 103I is formed in place of the structural body 103H.

The structural body 103I includes a low refractive index film 131I and a high refractive index film 132I formed so as to wrap the whole of the low refractive index film 131I. The high refractive index film 132I is formed by a material having a higher refractive index than that of the low refractive index film 131I (material such as aluminum oxide (AlOx)).

The vertical structure of the structural body 103I is a structure formed on the side surfaces of the color filter 141 and also within a groove 105I. As with the groove 105H (FIG. 18), the groove 105I has a structure such that the groove 105I penetrates only three layers on an upper side, that is, the third layer 123 to fifth layer 125 among the five layers of the antireflection film 102, and is stopped at the second layer 122 including hafnium oxide (HfOx) or the like.

On the other hand, the horizontal structure of the structural body 103I is a two-stage structure in which an upper portion thereof as a part upward of the upper surface of the antireflection film 102 and a lower portion thereof as a part within the groove 105H penetrating only the three layers of the antireflection film 102 are different in width from each other. That is, the structural body 103I has a structure such that the width of the upper portion is wider and thicker than the width of the lower portion.

As described above, whereas the width of the structural body 103H is uniform in the structure illustrated in FIG. 18, the width of the structural body 103I is not uniform and the width of the upper portion is wider than the width of the lower portion in the structure illustrated in FIG. 21. When such a structure is formed, the structural body 103 is not in contact with the second region 113 of polysilicon (Poly-Si) or the like, and overetching control is unnecessary at a time of manufacturing. There is thus an advantage of facilitating processing. In addition, the structural body 103 can be formed in an optimum shape for the pixel 100.

### Eleventh Example

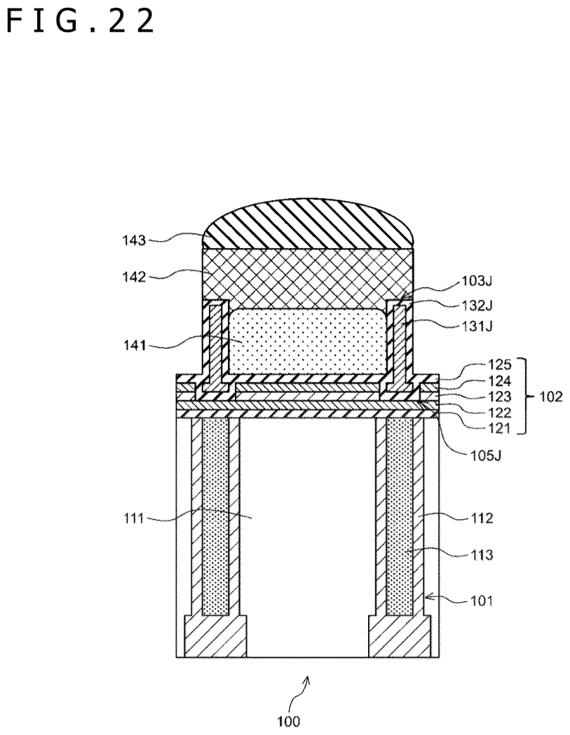

FIG. 22 is a diagram illustrating an eleventh example of the structure including the pixel 100.

In the structure illustrated in FIG. 22, as compared with the structure illustrated in FIG. 18, a structural body 103J is formed in place of the structural body 103H.

The structural body 103J includes a low refractive index film 131J and a high refractive index film 132J formed so as to wrap the whole of the low refractive index film 131J. The high refractive index film 132J is formed by a material having a higher refractive index than that of the low refractive index film 131J (material such as aluminum oxide (AlOx)).

The vertical structure of the structural body 103J is a structure formed on the side surfaces of the color filter 141 and also within a groove 105J. As with the groove 105H (FIG. 18), the groove 105J has a structure such that the groove 105J penetrates only three layers on an upper side, that is, the third layer 123 to fifth layer 125 among the five layers of the antireflection film 102, and is stopped at the second layer 122 including hafnium oxide (HfOx) or the like.

On the other hand, the horizontal structure of the structural body 103J is a two-stage structure in which the width of an upper portion thereof and the width of a lower portion thereof are different from each other. That is, the structural body 103J has a structure in which the width of the upper portion is narrower and thinner than the width of the lower portion.

As described above, whereas the width of the structural body 103H is uniform in the structure illustrated in FIG. 18, the width of the structural body 103J is not uniform and the width of the upper portion is narrower than the width of the lower portion in the structure illustrated in FIG. 22. When such a structure is formed, the structural body 103 is not in contact with the second region 113 of polysilicon (Poly-Si) or the like, and overetching control is unnecessary at a time of manufacturing. There is thus an advantage of facilitating processing. In addition, it is possible to increase the opening area of the photoelectric conversion region 111 and thus improve sensitivity in the pixel 100.

### Gist of Present Disclosure

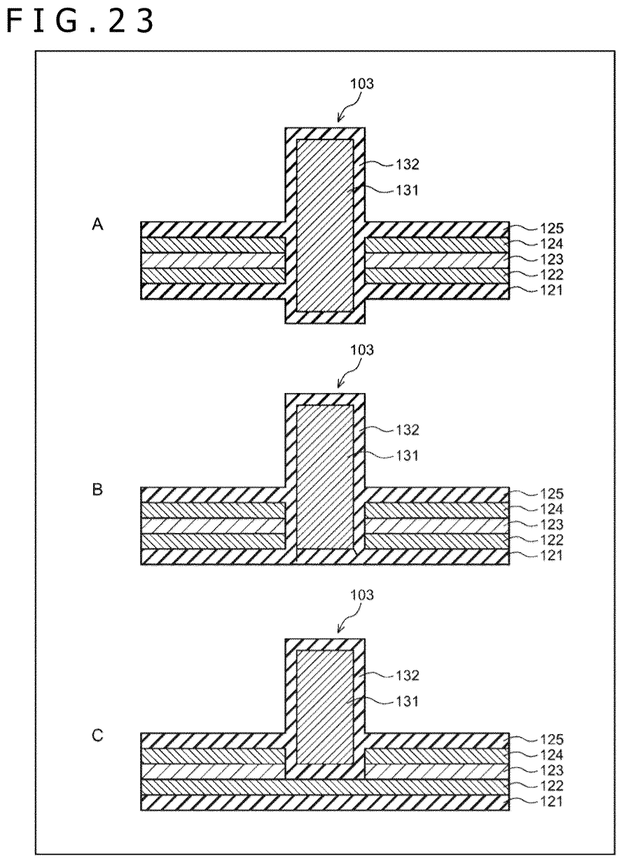

Finally, the gist of the first embodiment will be described with reference to FIG. 23.

As illustrated in A in FIG. 23, the structural body 103 has a structure including the low refractive index film 131 and the high refractive index film 132, and can be made to have a structure that penetrates the five layers of the antireflection film 102 and reaches the element isolation region 101. The structural body 103 is formed on the side surfaces of the color filter 141, and is formed in a lattice manner as viewed in plan.

As illustrated in B in FIG. 23, the structural body 103 can be made to have a structure that does not penetrate to the top surface of the silicon substrate. In addition, as illustrated in C in FIG. 23, the structural body 103 can be made to have a structure that does not penetrate a part of the layers of the antireflection film 102, such, for example, as being stopped at the second layer 122 including hafnium oxide (HfOx).

In the structural body 103, the high refractive index film 132 has such a structure as to cover the whole of the low refractive index film 131. It is therefore possible to reflect light (incident light) with a higher reflecting effect due to a difference between the refractive index of the material of the low refractive index film 131 and the refractive index of the material of the high refractive index film 132. Aluminum oxide (AlOx), for example, can be used as a material for the high refractive index film 132.

The reflecting effect may be decreased in a case where as the structural body 103, the low refractive index film 131 is combined with a film having a low refractive index such as silicon oxide (SiO₂). However, the effect of such a decrease can be reduced by adopting the structure such that the high refractive index film 132 covers the whole of the low refractive index film 131. In addition, because the whole of the low refractive index film 131 is covered by the high refractive index film 132, a protecting effect is provided.

As described above, in the solid-state imaging device 10, the structural body 103 is provided as a structure thereof. It is thereby possible, for example, to suppress a color mixture, improve sensitivity by increasing the opening area, and cope with miniaturization of the element isolation region 101. Therefore, sufficient sensor characteristics are obtained. As a result, the sensor characteristics can be improved.

### 2. Second Embodiment

### Configuration of Pixel

Description will be made of a structure including the pixels 200 arranged two-dimensionally in the pixel array unit 21 in the solid-state imaging device 10.

### First Example

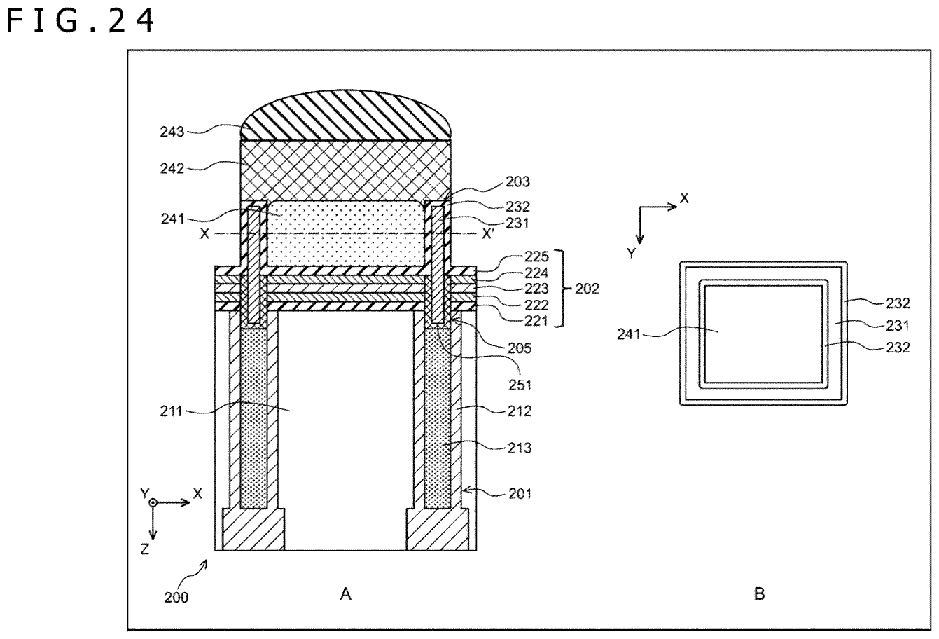

FIG. 24 is a diagram illustrating a first example of a structure including a pixel 200. A in FIG. 24 represents a sectional structure. B in FIG. 24 represents a plan view when the sectional structure in A in FIG. 24 is cut by a plane X-X′ indicated by alternate long and short dashed lines in the figure.

In A in FIG. 24, the pixel 200 has a photoelectric conversion region 211. The photoelectric conversion region 211, for example, includes a semiconductor region of a second conductivity type in a well region of a first conductivity type which well region is formed in a silicon substrate. A p-type can be set as the first conductivity type, and an n-type can be set as the second conductivity type.

The photoelectric conversion region 211 is electrically and optically isolated by an element isolation region 201. The element isolation region 201 is formed so as to surround the photoelectric conversion region 211. The element isolation region 201 includes an element isolation structure as an FFTI. The element isolation region 201 has a structure including a first region 212 and a second region 213 formed in a groove (trench). Silicon oxide (SiO₂), for example, is used as a material for the first region 212. Polysilicon (Poly-Si), for example, is used as a material for the second region 213.

An antireflection film 202 is formed on the upper surface of the silicon substrate in which the photoelectric conversion region 211 is formed. The antireflection film 202 is formed by laminating a first layer 221 to a fifth layer 225.

Aluminum oxide (AlOx) is used as a material for the first layer 221. Hafnium oxide (HfOx), for example, is used as a material for the second layer 222. Silicon oxide (SiO₂), for example, is used as a material for the third layer 223. Hafnium oxide (HfOx), for example, for example, is used as a material for the fourth layer 224. Aluminum oxide (AlOx), for example, is used as a material for the fifth layer 225. It is to be noted that the number of layers of the antireflection film 202 is not limited to five, and may be another number of layers.

A color filter 241 is formed on the upper surface of the antireflection film 202. A structural body 203 having a structure including a low refractive index film 231, a high refractive index film 232, and an insulating film 251 is formed on the side surfaces of the color filter 241. The structural body 203 is formed so as to surround the color filter 241. The structural body 203 can function as an inter-pixel light shielding film. In the structural body 203, the high refractive index film 232 is formed so as to cover a part of the low refractive index film 231.

The low refractive index film 231 is formed by a material having a lower refractive index than the high refractive index film 232. The high refractive index film 232 is formed by a material having a higher refractive index than that of the low refractive index film 231. For example, aluminum oxide (AlOx) can be used as a material for the high refractive index film 232, and a material having a lower refractive index than aluminum oxide (AlOx) can be used as a material for the low refractive index film 231.

The vertical structure of the structural body 203 is a structure formed not only on the side surfaces of the color filter 241 but also in a groove 205 that penetrates the antireflection film 202 and reaches an upper portion of the element isolation region 201. The insulating film 251 is formed on the side surfaces and bottom surface of the groove 205. The low refractive index film 231 is embedded within the groove 205 having the side surfaces and the bottom surface thereof covered by the insulating film 251. That is, in the structural body 203, the insulating film 251 is formed so as to cover a remaining part of the low refractive index film 231.

The insulating film 251 is formed to insulate a conductor such as polysilicon (Poly-Si) as the material of the second region 213 from high dielectric constant films such as aluminum oxide (AlOx) and hafnium oxide (HfOx) as the materials of the respective layers of the antireflection film 202. Silicon oxide (SiO₂), for example, can be used as a material for the insulating film 251. However, an SiCN film, an SiCO film, an SiCON film, an SiBN film, or the like may be used as a material for the insulating film 251.

As illustrated in a plan view of B in FIG. 24, the structural body 203 has a structure such that the low refractive index film 231 covered by the high refractive index film 232 and the insulating film 251 surrounds the color filter 241. Each of the pixels formed in the silicon substrate has a similar structure. That is, structural bodies 203 formed for the respective pixels arranged two-dimensionally in the pixel array unit 21 are arranged in a lattice manner, and are formed as a grid structure. In other words, the structural bodies 203 can also be said to be grid structural bodies.

A color filter corresponding to the wavelength of red (R), green (G), or blue (B), for example, can be used as the color filter 241. In addition, color filters corresponding to a Bayer array can be used as color filters 241 formed in the respective pixels arranged two-dimensionally in the pixel array unit 21. A planarizing film 242 and an on-chip microlens 243 are laminated on an upper surface of the color filter 241.

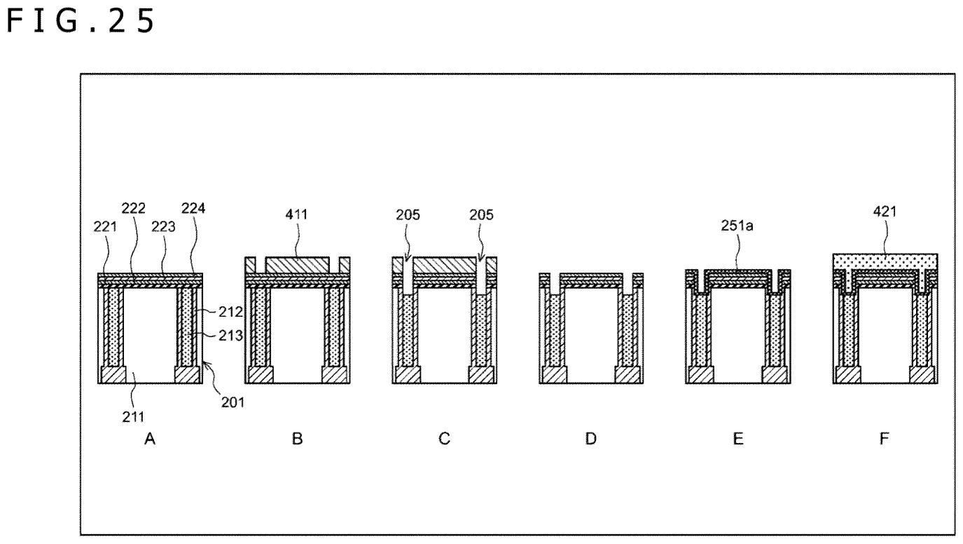

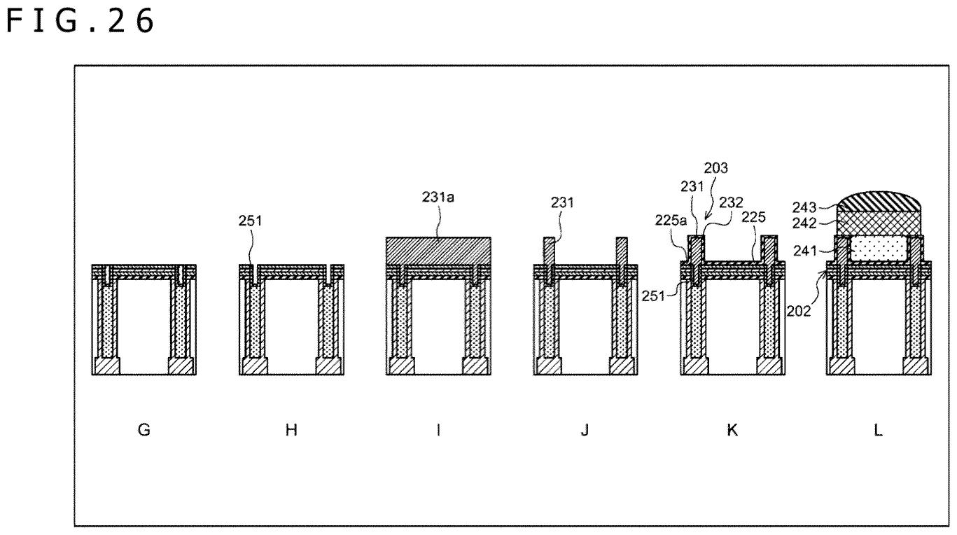

FIG. 25 and FIG. 26 are diagrams illustrating an example of a manufacturing method including processes for forming the structure illustrated in FIG. 24. In this manufacturing method, processes after the photoelectric conversion region 211 and the element isolation region 201 are formed in the silicon substrate are illustrated in process order. The same is true for the description of the following manufacturing methods.

First, in a process illustrated in A of FIG. 25, four layers as the first layer 221 to fourth layer 224 in a laminated state are formed on the upper surface of the silicon substrate in which the photoelectric conversion region 211 and the element isolation region 201 are formed. In a process illustrated in B in FIG. 25, a processing mask 411 having a predetermined pattern is formed on the four laminated layers.

In a process illustrated in C in FIG. 25, an unnecessary part is removed by processing the part corresponding to the pattern of the processing mask 411. The groove 205 is thereby formed. The groove 205 penetrates the first layer 221 to fourth layer 224, and the bottom surface of the groove 205 reaches an upper portion of the element isolation region 201. In a process illustrated in D in FIG. 25, the processing mask 411 is peeled off.

In a process illustrated in E in FIG. 25, a film 251a including silicon oxide (SiO₂) or the like as a material for the insulating film 251 is formed. In a process illustrated in F in FIG. 25, a sacrificial film 421 is formed so as to fill the groove 205. Next, as illustrated in G and H in FIG. 26, CMP (Chemical Mechanical Polishing) planarization is performed, and thereafter the sacrificial film 421 is peeled off. The insulating film 251 is thereby formed inside (side surfaces and bottom surface of) the groove 205.

In a process illustrated in I in FIG. 26, a film 231a including a material for the low refractive index film 231 is formed. Here, though detailed processes are omitted, as in G and H in FIG. 4 described above, the low refractive index film 231 is formed by forming a processing mask on the film 231a, thereafter processing a part corresponding to the pattern of the processing mask, and peeling off the processing mask (J in FIG. 26). In a process illustrated in K in FIG. 26, a film 225a including a material for the fifth layer 225 and the high refractive index film 232 is formed.

Consequently, a part (lower portion) of the low refractive index film 231 which part is embedded in the groove 205 is covered by the insulating film 251, and a part (upper portion) of the low refractive index film 231 which part juts in a shape of a projection from the antireflection film 202 is covered by the high refractive index film 232. The structural body 203 is thereby formed. In addition, the antireflection film 202 in which the first layer 221 to fifth layer 225 are laminated is formed. In a subsequent process, the color filter 241, the planarizing film 242, and the on-chip microlens 243 are laminated onto the antireflection film 202 in order (L in FIG. 26). The structure illustrated in FIG. 24 can be formed by undergoing such processes.

Because the structure as described above is provided, even when a conductor such as polysilicon (Poly-Si) is formed as the second region 213 of the element isolation region 201, and a potential is applied thereto, the insulating film 251 can insulate the conductor from the high dielectric constant films such as aluminum oxide (AlOx) and hafnium oxide (HfOx) as the materials of the respective layers of the antireflection film 202. Dielectric films are leaky, and therefore a leakage current can be reduced by providing insulation protection. In addition, power consumption during a standby time can be reduced by reducing the leakage current.

### Second Example

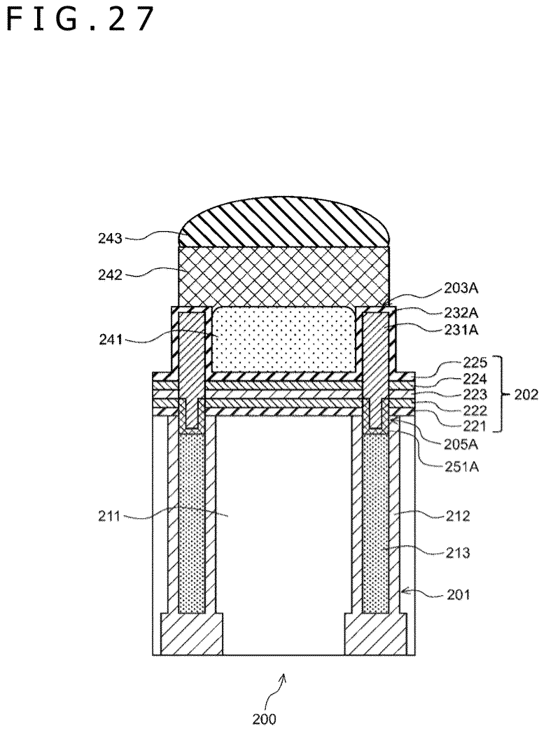

FIG. 27 is a diagram illustrating a second example of the structure including the pixel 200. In FIG. 27, parts corresponding to those in FIG. 24 are identified by the same reference signs, and description thereof will be omitted as appropriate. Incidentally, description of parts having the same reference signs also in the subsequent drawings will be omitted as appropriate.

In the structure illustrated in FIG. 27, as compared with the structure illustrated in FIG. 24, a structural body 203A is formed in place of the structural body 203.

The structural body 203A has a structure including a low refractive index film 231A, a high refractive index film 232A, and an insulating film 251A. The high refractive index film 232A is formed by a material having a higher refractive index than that of the low refractive index film 231A (material such as aluminum oxide (AlOx)). The insulating film 251A is formed by a material such as silicon oxide (SiO₂).

The vertical structure of the structural body 203A is such that the length in a vertical direction of the insulating film 251A formed in a groove 205A is shorter than the length in the vertical direction of the insulating film 251 (FIG. 24). Though the length in the vertical direction of the insulating film 251A is shortened as compared with the insulating film 251 (FIG. 24), the insulating film 251A can insulate the conductor such as polysilicon (Poly-Si) as the material of the second region 213 from the high dielectric constant films such as aluminum oxide (AlOx) and hafnium oxide (HfOx) as the materials of the respective layers of the antireflection film 202.

Thus, when the dielectrics can be insulated by forming the insulating film 251 between the conductor and the dielectric constant films, the length in the vertical direction of the insulating film 251 may be shortened. Even in the structure in which the length in the vertical direction of the insulating film 251 is shortened, insulation resistance can be improved, and a leakage current can be reduced. In addition, power consumption during a standby time can be reduced.

As for a manufacturing method including processes for forming the structure illustrated in FIG. 27, it suffices to further process the film 251a by etching or the like after the sacrificial film 421 is formed (F in FIG. 25) and CMP planarization is performed in the manufacturing method of FIG. 25 and FIG. 26. The insulating film 251A having a short length in the vertical direction can be formed on the side surfaces of the groove 205A by undergoing such processes.

### Third Example

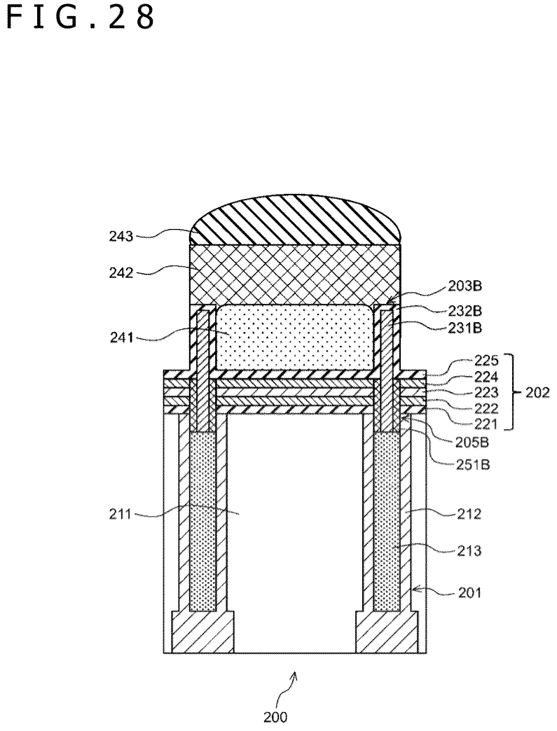

FIG. 28 is a diagram illustrating a third example of the structure including the pixel 200.

In the structure illustrated in FIG. 28, as compared with the structure illustrated in FIG. 24, a structural body 203B is formed in place of the structural body 203.

The structural body 203B has a structure including a low refractive index film 231B, a high refractive index film 232B, and an insulating film 251B. The high refractive index film 232B is formed by a material having a higher refractive index than that of the low refractive index film 231B (material such as aluminum oxide (AlOx)). The insulating film 251B is formed by a material such as silicon oxide (SiO₂).

In the structural body 203B, the insulating film 251B formed in a groove 205B is formed only on the side surfaces of the groove 205B and is not formed on the bottom surface of the groove 205B. As compared with the insulating film 251 (FIG. 24), the insulating film 251B is formed only on the side surfaces of the groove 205B. However, the insulating film 251B can insulate the conductor such as polysilicon (Poly-Si) as the material of the second region 213 from the high dielectric constant films such as aluminum oxide (AlOx) and hafnium oxide (HfOx) as the materials of the respective layers of the antireflection film 202.

Thus, when the dielectrics can be insulated by forming the insulating film 251 between the conductor and the dielectric constant films, the insulating film 251 does not necessarily need to be formed on the bottom surface of the groove 205. Even in the structure in which the insulating film 251 is formed only on the side surfaces of the groove 205, insulation resistance can be improved, and a leakage current can be reduced. In addition, power consumption during a standby time can be reduced.

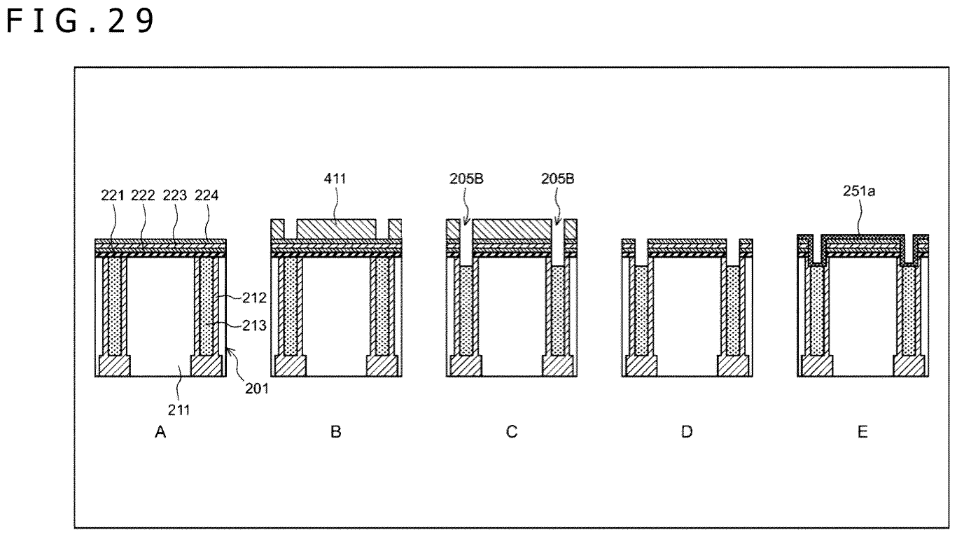

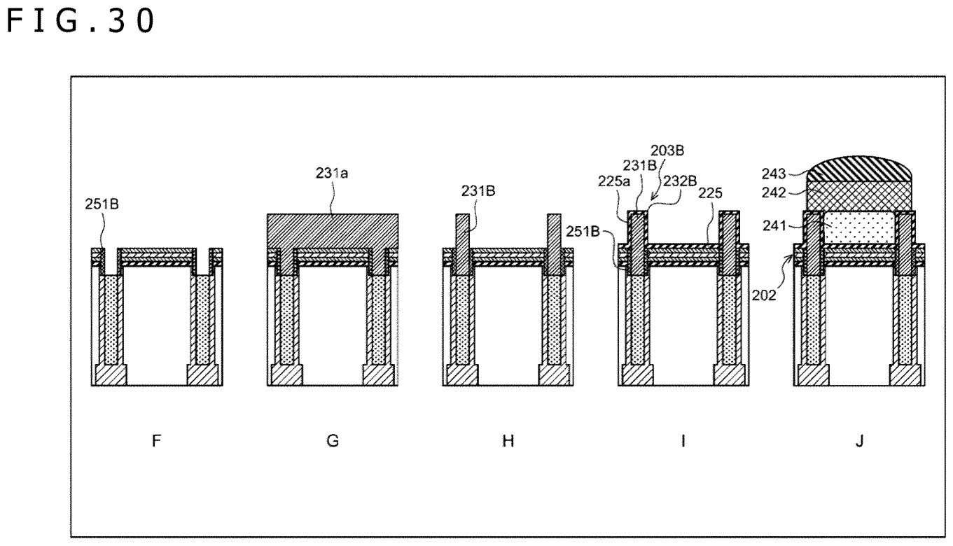

FIG. 29 and FIG. 30 are diagrams illustrating an example of a manufacturing method including processes for forming the structure illustrated in FIG. 28.

In A to E in FIG. 29, as in A to E in FIG. 25, the groove 205B is formed by processing a part corresponding to the pattern of the processing mask 411, and thereafter a film 251a including a material for the insulating film 251B is formed.

In a process illustrated in F in FIG. 30, only the film 251a formed on the side surfaces of the groove 205B is made to remain by performing processing using RIE (Reactive Ion Etching). The insulating film 251B can be thereby formed.

In G to J in FIG. 30, as in I to L in FIG. 26, the low refractive index film 231B is formed by forming and processing the film 231a (H in FIG. 30). In addition, the film 225a is formed, and consequently the fifth layer 225 and the high refractive index film 232B are formed (I in FIG. 30). The structural body 203B is thereby formed. Then, the color filter 241, the planarizing film 242, and the on-chip microlens 243 are laminated onto the antireflection film 202 in order (J in FIG. 30). The structure illustrated in FIG. 28 can be formed by undergoing such processes.

### Fourth Example

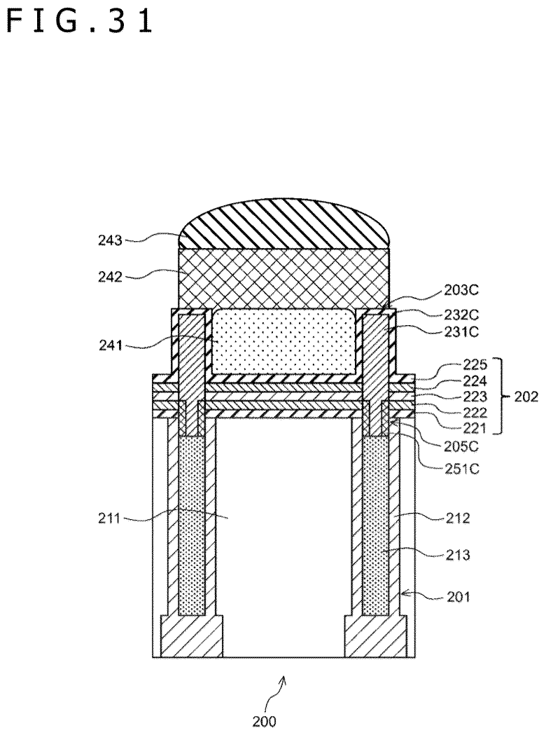

FIG. 31 is a diagram illustrating a fourth example of the structure including the pixel 200.

In the structure illustrated in FIG. 31, as compared with the structure illustrated in FIG. 28, a structural body 203C is formed in place of the structural body 203B.

The structural body 203C has a structure including a low refractive index film 231C, a high refractive index film 232C, and an insulating film 251C. The high refractive index film 232C is formed by a material having a higher refractive index than that of the low refractive index film 231C (material such as aluminum oxide (AlOx)). The insulating film 251C is formed by a material such as silicon oxide (SiO₂).

The vertical structure of the structural body 203C is such that the length in the vertical direction of the insulating film 251C formed in a groove 205C is shorter than the length in the vertical direction of the insulating film 251B (FIG. 28). Though the length in the vertical direction of the insulating film 251C is shortened as compared with the insulating film 251B (FIG. 28), the insulating film 251C can insulate the conductor such as polysilicon (Poly-Si) as the material of the second region 213 from the high dielectric constant films such as aluminum oxide (AlOx) and hafnium oxide (HfOx) as the materials of the respective layers of the antireflection film 202.

Thus, when the dielectrics can be insulated by forming the insulating film 251 between the conductor and the dielectric constant films, the insulating film 251 does not need to be formed on the bottom surface of the groove 205, and further the length in the vertical direction of the insulating film 251 may be shortened. Even in the structure in which the insulating film 251 is formed only on the side surfaces of the groove 205, and the length in the vertical direction of the insulating film 251 is shortened, insulation resistance can be improved, and a leakage current can be reduced. In addition, power consumption during a standby time can be reduced.

As for a manufacturing method including processes for forming the structure illustrated in FIG. 31, it suffices to further process the film 251a by etching or the like when performing processing using RIE such that the film 251a formed on the side surfaces of the groove 205 remains in the manufacturing method of FIG. 29 and FIG. 30 (F in FIG. 30). The insulating film 251C having a short length in the vertical direction can be formed on the side surfaces of the groove 205C by undergoing such processes.

### Fifth Example

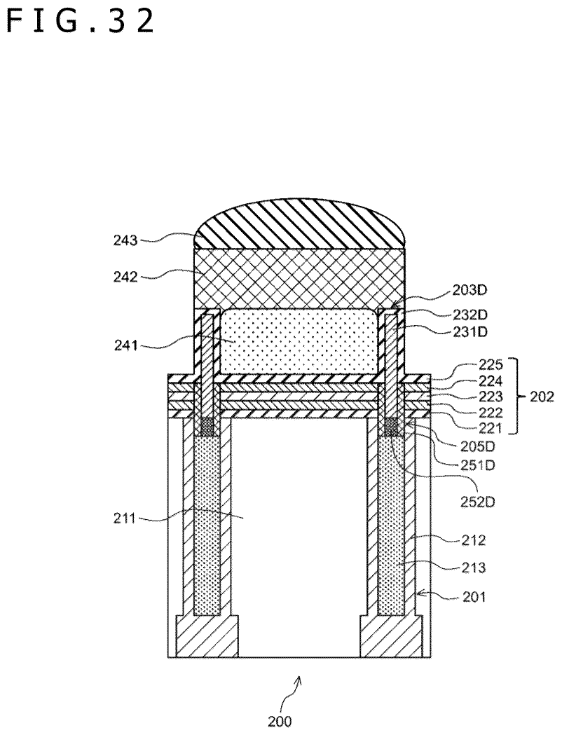

FIG. 32 is a diagram illustrating a fifth example of the structure including the pixel 200.

In the configuration illustrated in FIG. 32, as compared with the structure illustrated in FIG. 24, a structural body 203D is formed in place of the structural body 203.

The structural body 203D has a structure including a low refractive index film 231D, a high refractive index film 232D, an insulating film 251D, and a conductor film 252D. The high refractive index film 232D is formed by a material having a higher refractive index than that of the low refractive index film 231D (material such as aluminum oxide (AlOx)). The insulating film 251D is formed by a material such as silicon oxide (SiO₂).

A titanium-based compound, for example, can be used as a material for the conductor film 252D. Films of the titanium-based compound include a TiN film, a TiSiN film, a TiBN film, and the like. Incidentally, in the following description, in cases where conductor films in respective structures do not need to be distinguished from each other, the conductor films will be referred to as a conductor film 252.

In the structural body 203D, the insulating film 251D formed in a groove 205D is formed only on the side surfaces of the groove 205D and is not formed on the bottom surface of the groove 205D. The conductor film 252D is formed on the bottom surface of the groove 205D. Though the insulating film 251D is formed only on the side surfaces of the groove 205D, and the conductor film 252D is formed on the bottom surface of the groove 205D, the insulating film 251D can insulate the conductor such as polysilicon (Poly-Si) as the material of the second region 213 from the high dielectric constant films such as aluminum oxide (AlOx) and hafnium oxide (HfOx) as the materials of the respective layers of the antireflection film 202.

Thus, when the dielectrics can be insulated by forming the insulating film 251 between the conductor and the dielectric constant films, the conductor film 252 may be formed on the bottom surface of the groove 205. Even in the structure in which the insulating film 251 is formed only on the side surfaces of the groove 205, and the conductor film 252 is formed on the bottom surface of the groove 205, insulation resistance can be improved, and a leakage current can be reduced. In addition, power consumption during a standby time can be reduced.

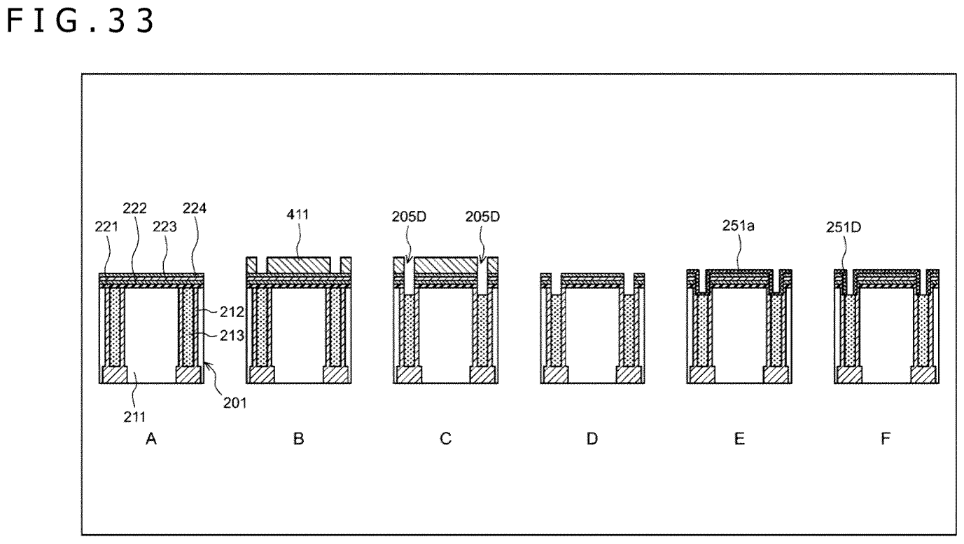

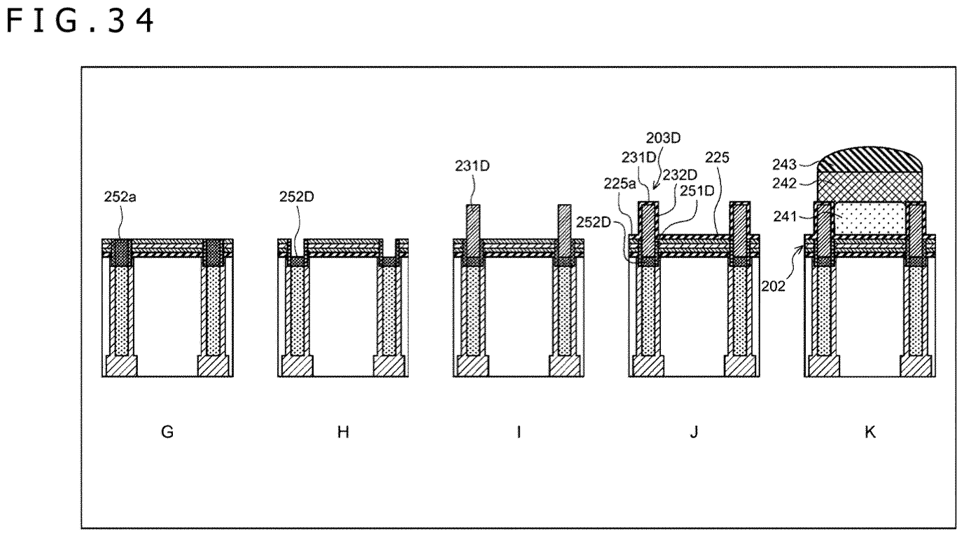

FIG. 33 and FIG. 34 are diagrams illustrating an example of a manufacturing method including processes for forming the structure illustrated in FIG. 32.

In processes illustrated in A to E in FIG. 33, as in the processes illustrated in A to E in FIG. 25, the groove 205D is formed by processing a part corresponding to the pattern of the processing mask 411, and thereafter the film 251a including a material for the insulating film 251D is formed.

In a process illustrated in F in FIG. 33, as in the process illustrated in F in FIG. 30, only the film 251a formed on the side surfaces of the groove 205D is made to remain by performing processing using RIE. The insulating film 251D can be thereby formed.

In a process illustrated in G in FIG. 34, a film 252a including a material for the conductor film 252D is formed, and thereafter CMP planarization is performed. In a process illustrated in H in FIG. 34, the conductor film 252D is formed on the bottom surface of the groove 205D by processing the film 252a embedded in the groove 205D by etching or the like.

In processes illustrated in I to K in FIG. 34, as in the processes illustrated in I to L in FIG. 26, the low refractive index film 231D is formed by forming and processing the film 231a (I in FIG. 34). In addition, the film 225a is formed, and consequently the fifth layer 225 and the high refractive index film 232D are formed (J in FIG. 34). Then, the color filter 241, the planarizing film 242, and the on-chip microlens 243 are laminated onto the antireflection film 202 in order (K in FIG. 34). The structure illustrated in FIG. 32 can be formed by undergoing such processes.

### Sixth Example

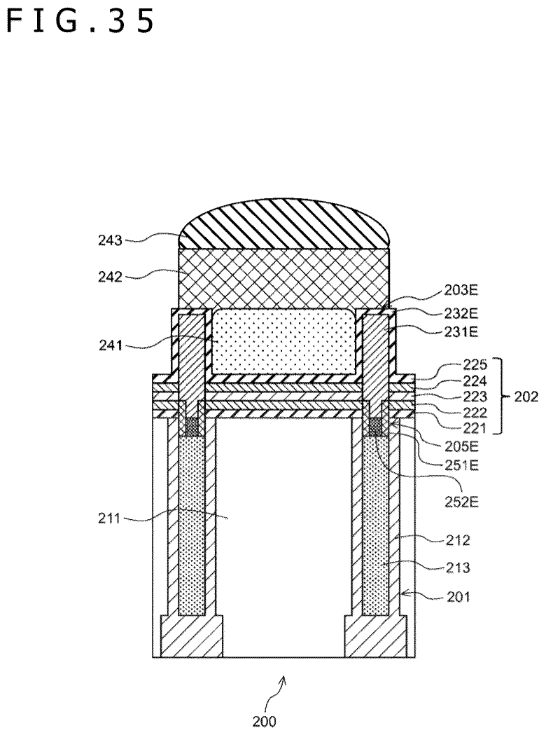

FIG. 35 is a diagram illustrating a sixth example of the structure including the pixel 200.

In the structure illustrated in FIG. 35, as compared with the structure illustrated in FIG. 32, a structural body 203E is formed in place of the structural body 203D.

The structural body 203E has a structure including a low refractive index film 231E, a high refractive index film 232E, an insulating film 251E, and a conductor film 252E. The high refractive index film 232E is formed by a material having a higher refractive index than that of the low refractive index film 231E (material such as aluminum oxide (AlOx)). The insulating film 251E is formed by a material such as silicon oxide (SiO₂). The conductor film 252E is formed by a material such as a titanium-based compound.

The vertical structure of the structural body 203E is such that the length in the vertical direction of the insulating film 251E formed in a groove 205E is shorter than the length in the vertical direction of the insulating film 251D (FIG. 32). Though the length in the vertical direction of the insulating film 251E is shortened as compared with the insulating film 251D (FIG. 32), the insulating film 251E can insulate the conductor such as polysilicon (Poly-Si) as the material of the second region 213 from the high dielectric constant films such as aluminum oxide (AlOx) and hafnium oxide (HfOx) as the materials of the respective layers of the antireflection film 202.

Thus, when the dielectrics can be insulated by forming the insulating film 251E between the conductor and the dielectric constant films, the conductor film 252 may be formed on the bottom surface of the groove 205, and further the length in the vertical direction of the insulating film 251 on the side surfaces of the groove 205 may be shortened. Even in the structure in which the insulating film 251 is formed only on the side surfaces of the groove 205, the conductor film 252 is formed on the bottom surface of the groove 205, and the length in the vertical direction of the insulating film 251 is shortened, insulation resistance can be improved, and a leakage current can be reduced. In addition, power consumption during a standby time can be reduced.

As for a manufacturing method including processes for forming the structure illustrated in FIG. 35, it suffices to further process the film 251a by etching or the like when performing processing using RIE such that the film 251a formed on the side surfaces of the groove 205 remains in the manufacturing method of FIG. 33 and FIG. 34 (F in FIG. 33). The insulating film 251E having a short length in the vertical direction can be formed on the side surfaces of the groove 205E by undergoing such processes.

### Seventh Example

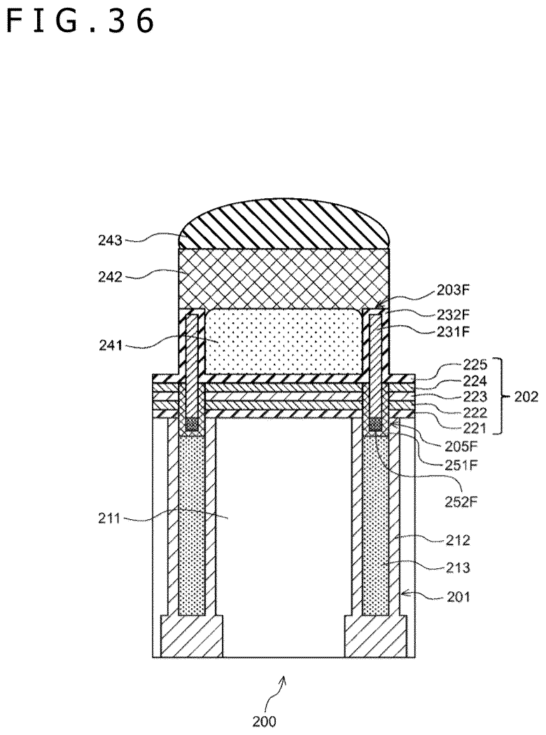

FIG. 36 is a diagram illustrating a seventh example of the structure including the pixel 200.

In the structure illustrated in FIG. 36, as compared with the structure illustrated in FIG. 24, a structural body 203F is formed in place of the structural body 203.

The structural body 203F has a structure including a low refractive index film 231F, a high refractive index film 232F, an insulating film 251F, and a conductor film 252F. The high refractive index film 232F is formed by a material having a higher refractive index than that of the low refractive index film 231F (material such as aluminum oxide (AlOx)). The insulating film 251F is formed by a material such as silicon oxide (SiO₂). The conductor film 252F is formed by a material such as a titanium-based compound.

In the structural body 203F, the insulating film 251F is formed on the side surfaces and bottom surface of a groove 205F, and the conductor film 252F is formed on the insulating film 251F formed on the bottom surface of the groove 205F. That is, in the groove 205F, a structure is formed such that the insulating film 251F covers a lower layer of the conductor film 252F, and such that the insulating film 251F protects the bottom surface and side surfaces of the groove 205F.

Though the insulating film 251F is formed on the side surfaces of the groove 205F, and the insulating film 251F and the conductor film 252F are formed on the bottom surface of the groove 205F, the conductor such as polysilicon (Poly-Si) as the material of the second region 213 can be insulated from the high dielectric constant films such as aluminum oxide (AlOx) and hafnium oxide (HfOx) as the materials of the respective layers of the antireflection film 202.

Thus, when the dielectrics can be insulated by forming the insulating film 251 between the conductor and the dielectric constant films, the insulating film 251 and the conductor film 252 may be formed on the bottom surface of the groove 205. Even in the structure in which the insulating film 251 is formed on the side surfaces of the groove 205, and the insulating film 251 and the conductor film 252 are laminated on the bottom surface of the groove 205, insulation resistance can be improved, and a leakage current can be reduced. In addition, power consumption during a standby time can be reduced.

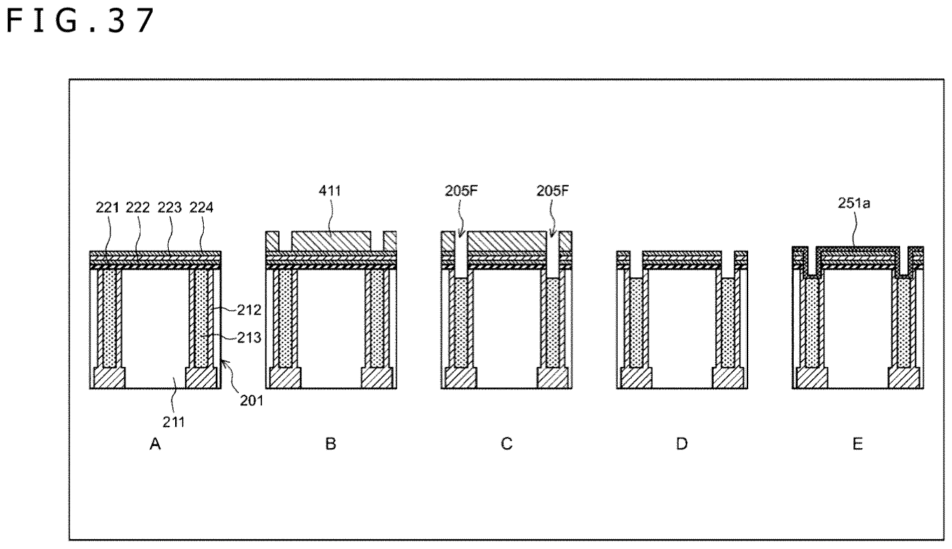

FIGS. 37 to 39 are diagrams illustrating an example of a manufacturing method including processes for forming the structure illustrated in FIG. 36.

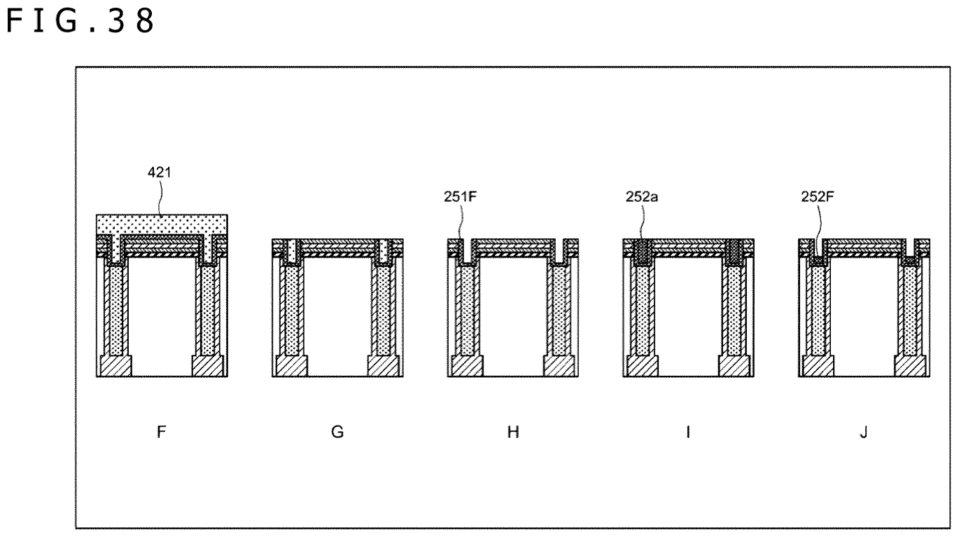

In processes illustrated in A to E in FIG. 37, as in the processes illustrated in A to E in FIG. 25, the groove 205F is formed by processing a part corresponding to the pattern of the processing mask 411, and thereafter the film 251a is formed. In processes illustrated in F to H in FIG. 38, as in the processes illustrated in F in FIG. 25 to H in FIG. 26, the sacrificial film 421 is formed, CMP planarization is performed, and the sacrificial film 421 is peeled off. The insulating film 251F is thereby formed.

In a process illustrated in I in FIG. 38, the film 252a including a material for the conductor film 252F is formed, and thereafter CMP planarization is performed. In a process illustrated in J in FIG. 38, the film 252a embedded in the groove 205F is processed by etching or the like. The conductor film 252F is thereby formed on the insulating film 251F formed on the bottom surface of the groove 205F.

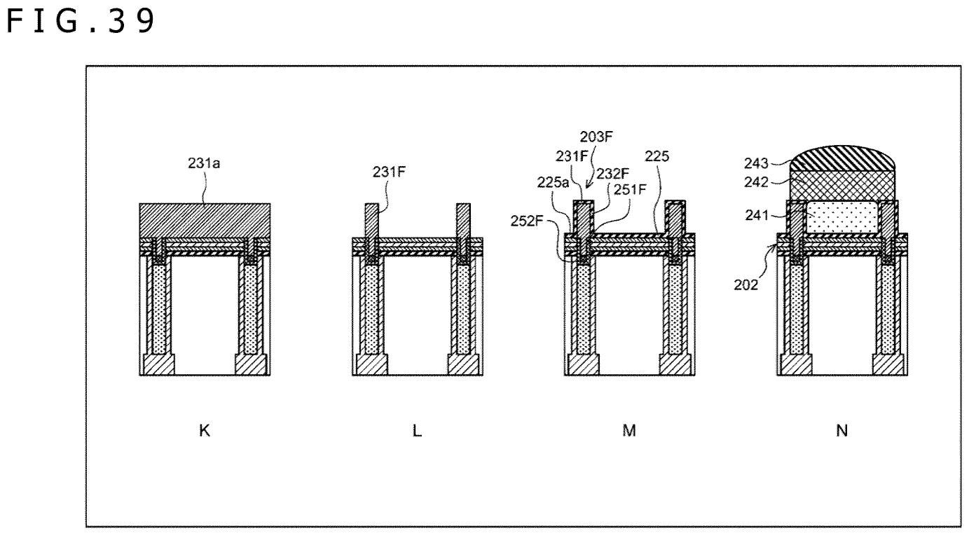

In processes illustrated in K to N in FIG. 39, as in the processes illustrated in I to L in FIG. 26, the low refractive index film 231F is formed by forming and processing the film 231a (L in FIG. 39). In addition, the film 225a is formed, and consequently the fifth layer 225 and the high refractive index film 232F are formed (M in FIG. 39). Then, the color filter 241, the planarizing film 242, and the on-chip microlens 243 are laminated onto the antireflection film 202 in order (N in FIG. 39). The structure illustrated in FIG. 36 can be formed by undergoing such processes.

### Eighth Example

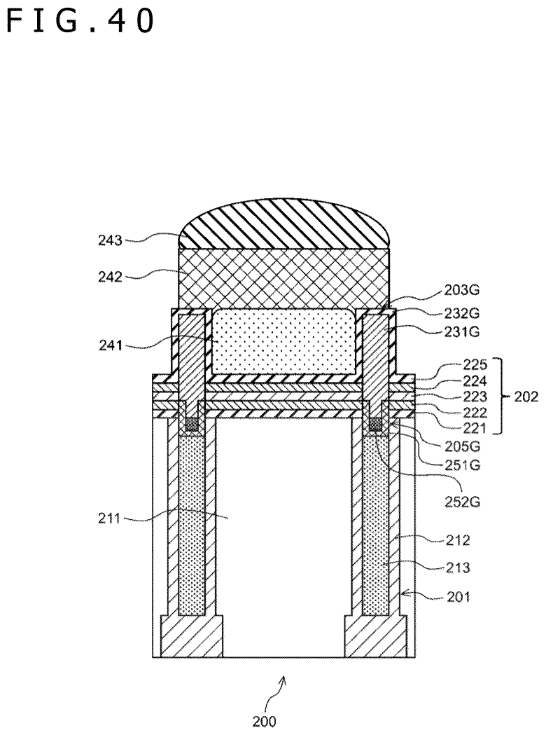

FIG. 40 is a diagram illustrating an eighth example of the structure including the pixel 200.

In the structure illustrated in FIG. 40, as compared with the structure illustrated in FIG. 36, a structural body 203G is formed in place of the structural body 203F.

The structural body 203G has a structure including a low refractive index film 231G, a high refractive index film 232G, an insulating film 251G, and a conductor film 252G. The high refractive index film 232G is formed by a material having a high refractive index than the low refractive index film 231G (material such as aluminum oxide (AlOx)). The insulating film 251G is formed by a material such as silicon oxide (SiO₂). The conductor film 252G is formed by a material such as a titanium-based compound.

The vertical structure of the structural body 203G is such that the length in the vertical direction of the insulating film 251G formed in a groove 205G is shorter than the length in the vertical direction of the insulating film 251F (FIG. 36). Though the length in the vertical direction of the insulating film 251G is shortened as compared with the insulating film 251F (FIG. 36), the insulating film 251G can insulate the conductor such as polysilicon (Poly-Si) as the material of the second region 213 from the high dielectric constant films such as aluminum oxide (AlOx) and hafnium oxide (HfOx) as the materials of the respective layers of the antireflection film 202.

Thus, when the dielectrics can be insulated by forming the insulating film 251 between the conductor and the dielectric constant films, the insulating film 251 and the conductor film 252 may be formed on the bottom surface of the groove 205, and further the length in the vertical direction of the insulating film 251 on the side surfaces of the groove 205 may be shortened. Even in the structure in which the insulating film 251 is formed on the side surfaces and bottom surface of the groove 205, the insulating film 251 and the conductor film 252 are laminated at the bottom surface, and the length in the vertical direction of the insulating film 251 formed on the side surfaces is shortened, insulation resistance can be improved, and a leakage current can be reduced. In addition, power consumption during a standby time can be reduced.

As for a manufacturing method including processes for forming the structure illustrated in FIG. 40, it suffices to further process the film 251a by etching or the like when forming the sacrificial film 421 and performing CMP planarization such that the film 251a formed in the groove 205F remains in the manufacturing method of FIGS. 37 to 39. The insulating film 251G having a short length in the vertical direction can be formed on the side surfaces of the groove 205G by undergoing such processes.

### Gist of Present Disclosure

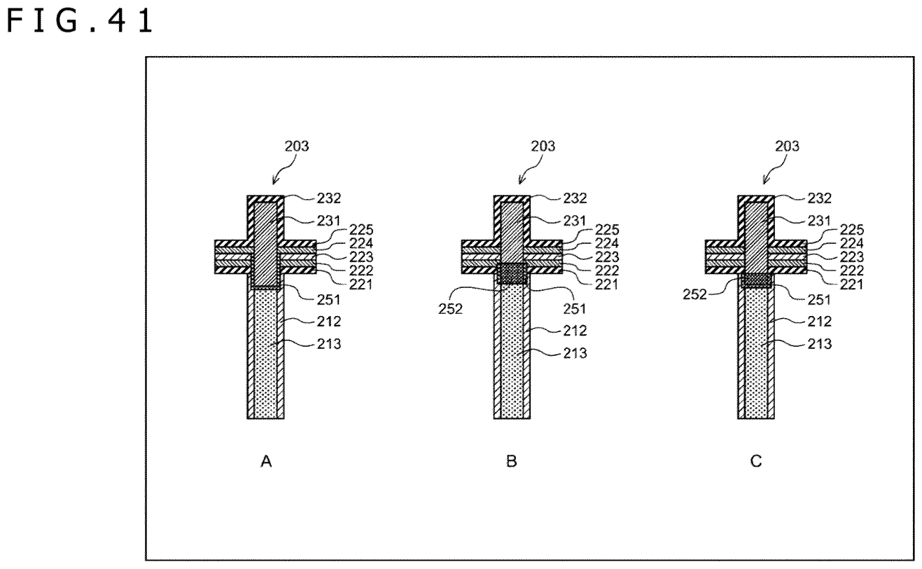

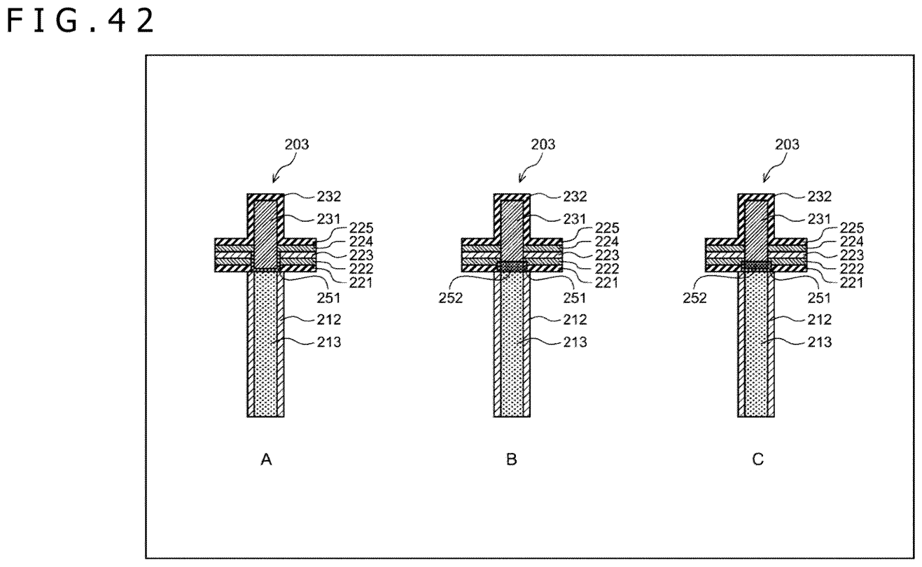

Finally, the gist of the second embodiment will be described with reference to FIG. 41 and FIG. 42.

As illustrated in A in FIG. 41, the structural body 203 has a structure including the low refractive index film 231, the high refractive index film 232, and the insulating film 251, and the insulating film 251 has a structure that insulates the conductor in the element isolation region 201 from the dielectrics included in the antireflection film 202. The structural body 203 is formed on the side surfaces of the color filter 241, and is formed in a lattice manner as viewed in plan.

As illustrated in B in FIG. 41, the structural body 203 may further include the conductor film 252, and can have a structure in which the insulating film 251 is formed on the side surfaces of the groove 205, and the conductor film 252 is formed on the bottom surface of the groove 205. In addition, as illustrated in C in FIG. 41, a structure may be adopted in which the insulating film 251 is formed on the side surfaces and bottom surface of the groove 205, and the conductor film 252 is formed at the bottom surface of the groove 205.

Because such a structure is provided, even when a conductor such as polysilicon (Poly-Si) is formed as the second region 213 of the element isolation region 201, and a potential is applied thereto, the insulating film 251 can insulate the conductor from the high dielectric constant films such as aluminum oxide (AlOx) and hafnium oxide (HfOx) as the materials of the respective layers of the antireflection film 202. Consequently, insulation resistance can be improved, and a leakage current can be reduced. In addition, power consumption during a standby time can be reduced.

Incidentally, when the dielectrics can be insulated by forming the insulating film 251 between the conductor and the dielectric constant films, a structure such that the lower surface of the structural body 203 coincides with the lower surface of the antireflection film 202 may be adopted, as illustrated in A to C in FIG. 42.

As described above, in the solid-state imaging device 10, by providing the structural body 203 as a structure thereof, it is possible, for example, to improve insulation resistance, and reduce a leakage current. Therefore, sufficient sensor characteristics are obtained. As a result, the sensor characteristics can be improved.

### 3. Modifications

In the above description, a CMOS solid-state imaging device has been described as the solid-state imaging device 10. The CMOS solid-state imaging device can have a back surface irradiation structure in which light is made incident from an upper layer (undersurface side) on an opposite side from a wiring layer side (top surface side) formed in a lower layer as viewed from the silicon substrate in which a photodiode as the photoelectric conversion region is formed. Incidentally, the CMOS solid-state imaging device may have a front surface irradiation structure in which the side from which light is made incident is the wiring layer side (top surface side).

The solid-state imaging device 10 is an example of a light detecting device to which the present disclosure is applied. That is, the light detecting device to which the present disclosure is applied is not limited to the solid-state imaging device 10, but can be applied to devices that detect light, such, for example, as a distance measuring sensor using an IR laser and the like. It is to be noted that the configurations of the structural bodies to which the present disclosure is applied are not limited to CMOS solid-state imaging devices, but can also be applied to CCD (Charge Coupled Device) solid-state imaging devices.

In the above description, the solid-state imaging device 10 is configured such that the first conductivity type is a p-type and the second conductivity type is an n-type. However, the n-type may be the first conductivity type, and the p-type may be the second conductivity type. In addition, in the above description, a configuration has been illustrated in which primary color filters corresponding to the wavelengths of red (R), green (G), and blue (B) are used as the color filters 141 or the color filters 241 in the solid-state imaging device 10. However, complementary color filters corresponding to the wavelengths of cyan (C), magenta (M), and yellow (Y) may be used.

### Configuration of Electronic Apparatus

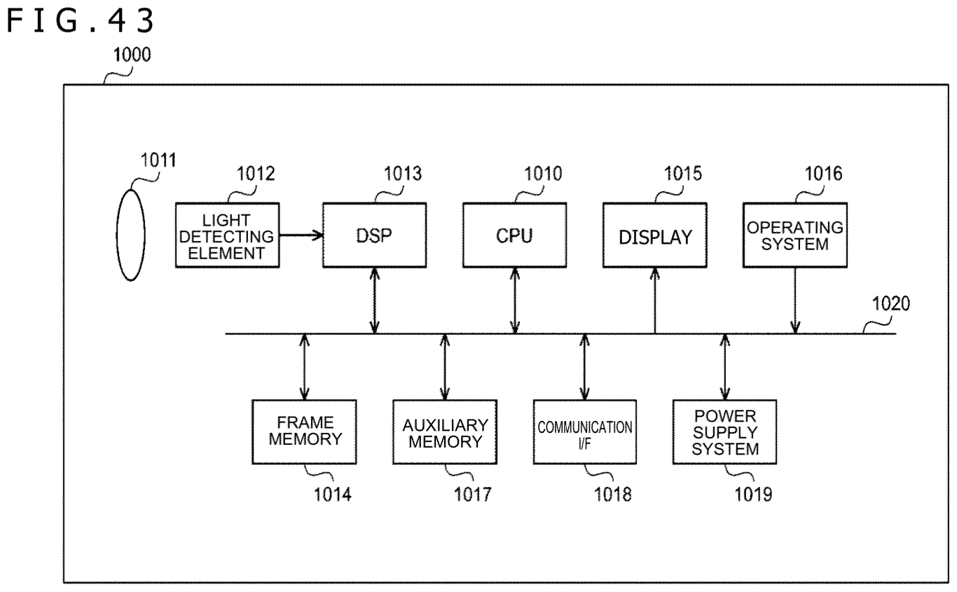

The light detecting device to which the present disclosure is applied can be included in an electronic apparatus such as a smart phone, a tablet terminal, a mobile telephone, a digital still camera, or a digital video camera. FIG. 43 is a diagram illustrating an example of a configuration of an electronic apparatus including the light detecting device to which the present disclosure is applied.

In FIG. 43, an electronic apparatus 1000 has an imaging system including an optical system 1011 including a lens group, a light detecting element 1012 having functions corresponding to those of the solid-state imaging device 10 in FIG. 1, and a DSP (Digital Signal Processor) 1013 as a camera signal processing unit. In addition to the imaging system, the electronic apparatus 1000 has a configuration in which a CPU (Central Processing Unit) 1010, a frame memory 1014, a display 1015, an operating system 1016, an auxiliary memory 1017, a communication I/F 1018, and a power supply system 1019 are interconnected via a bus 1020.

The CPU 1010 controls operation of various parts of the electronic apparatus 1000.

The optical system 1011 captures incident light (image light) from a subject, and forms an image on a light detecting surface of the light detecting element 1012. The light detecting element 1012 converts a light amount of the incident light whose image is formed on the light detecting surface by the optical system 1011 into an electric signal in pixel units, and outputs the electric signal as a pixel signal. The DSP 1013 performs predetermined signal processing on the signal output from the light detecting element 1012.

The frame memory 1014 temporarily records image data of a still image or a moving image imaged by the imaging system. The display 1015 is a liquid crystal display or an organic EL display. The display 1015 displays the still image or the moving image imaged by the imaging system. The operating system 1016 issues operation commands for various functions possessed by the electronic apparatus 1000 according to operations of a user.

The auxiliary memory 1017 is a storage medium including a semiconductor memory such as a flash memory. The auxiliary memory 1017 records the image data of the still image or the moving image imaged by the imaging system. The communication I/F 1018 has a communication module that supports a predetermined communication system. The communication I/F 1018 transmits the image data of the still image or the moving image imaged by the imaging system to another apparatus via a network.

The power supply system 1019 has, as supply targets, the CPU 1010, the DSP 1013, the frame memory 1014, the display 1015, the operating system 1016, the auxiliary memory 1017, and the communication I/F 1018, and supplies various kinds of power as operation power as appropriate.

It is to be noted that embodiments of the present disclosure are not limited to the foregoing embodiments, but are susceptible of various changes without departing from the spirit of the present disclosure.

The effects described in the present specification are illustrative only and are not limited, and there may be other effects. Incidentally, in the present specification, an expression of “as viewed in plan” will be used when indicating positional relation between parts projected onto a plane parallel with the top surface of the silicon substrate (semiconductor substrate). In addition, an expression of “as viewed in section” will be used when indicating positional relation between parts projected onto a plane perpendicular to the top surface of the silicon substrate (semiconductor substrate).

In addition, the present disclosure can adopt the following configurations.
(1)

A light detecting device including:
a plurality of pixels each having a photoelectric conversion region, in which
a structural body is formed in a lattice manner as viewed in plan on a semiconductor substrate in which the photoelectric conversion region is formed, the structural body having a first film including a first material and a second film including a second material different from the first material.
(2)

The light detecting device according to (1) above, in which
the first film is a low refractive index film in which the first material has a predetermined refractive index.
(3)

The light detecting device according to (1) or (2) above, in which
the second film is a high refractive index film in which the second material has a higher refractive index than that of the first material.
(4)

The light detecting device according to (3) above, in which
the second material is aluminum oxide (AlOx).
(5)

The light detecting device according to any one of (1) to (4) above, in which
the structural body has a structure that reaches an element isolation region formed in the semiconductor substrate, as viewed in section.
(6)

The light detecting device according to (5) above, in which
the structural body has a structure that is thinner than the element isolation region as viewed in section.
(7)

The light detecting device according to (5) above, in which
the structural body has a structure that is thinner than a region formed within the element isolation region, as viewed in section.
(8)

The light detecting device according to (5) above, in which
the structural body has a structure that is thicker than the element isolation region as viewed in section.
(9)

The light detecting device according to (5) above, in which
the structural body has a two-stage structure in which an upper portion and a lower portion are different in thickness from each other as viewed in section.
(10)

The light detecting device according to (9) above, in which
the upper portion has a structure that is thicker than the lower portion.
(11)

The light detecting device according to (9) above, in which
the upper portion has a structure that is thinner than the lower portion.
(12)

The light detecting device according to any one of (1) to (4) above, in which
the structural body has a structure that does not penetrate the semiconductor substrate as viewed in section.
(13)

The light detecting device according to (12) above, in which
the structural body has a two-stage structure in which an upper portion and a lower portion are different in thickness from each other as viewed in section.
(14)

The light detecting device according to (13) above, in which
the upper portion has a structure that is thicker than the lower portion.
(15)

The light detecting device according to (13) above, in which
the upper portion has a structure that is thinner than the lower portion.
(16)

The light detecting device according to any one of (1) to (4) above, in which
the structural body has a structure that does not penetrate a part of layers of an antireflection film formed on the semiconductor substrate, as viewed in section.
(17)

The light detecting device according to (16) above, in which
the structural body has a two-stage structure in which an upper portion and a lower portion are different in thickness from each other as viewed in section.
(18)

The light detecting device according to (17) above, in which
the upper portion has a structure that is thicker than the lower portion.
(19)

The light detecting device according to (17) above, in which
the upper portion has a structure that is thinner than the lower portion.
(20)

The light detecting device according to any one of (1) to (19) above, in which
the second film is formed so as to cover a whole of the first film, and
the structural body is formed on side surfaces of a color filter, and formed in a lattice manner as viewed in plan for the color filter.
(21)

An electronic apparatus including:
a light detecting device including
   a plurality of pixels each having a photoelectric conversion region, in which
   a structural body is formed in a lattice manner as viewed in plan on a semiconductor substrate in which the photoelectric conversion region is formed, the structural body having a first film including a first material and a second film including a second material different from the first material.
(22)

A light detecting device including:
a plurality of pixels each having a photoelectric conversion region, in which
a conductor is formed in an element isolation region formed in a semiconductor substrate in which the photoelectric conversion region is formed, and a potential is applied to the conductor, and
a structural body is formed in a lattice manner as viewed in plan on the semiconductor substrate, the structural body having a first film including a first material, a second film including a second material different from the first material, and a third film including a third material different from the first material and the second material.
(23)

The light detecting device according to (22) above, in which
the first film is a low refractive index film in which the first material has a predetermined refractive index,
the second film is a high refractive index film in which the second material has a higher refractive index than that of the first material, and
the third film is an insulating film.
(24)

The light detecting device according to (23) above, in which
the second material is aluminum oxide (AlOx).
(25)

The light detecting device according to (23) or (24) above, in which
the third material is silicon oxide (SiO₂).
(26)

The light detecting device according to any one of (22) to (25) above, in which
the structural body has a structure in which the third film insulates the conductor in the element isolation region from a dielectric included in an antireflection film formed on the semiconductor substrate.
(27)

The light detecting device according to (26) above, in which
the third film is formed on side surfaces and a bottom surface of a groove in which the first film is formed, as viewed in section.
(28)

The light detecting device according to (26) above, in which
the third film is formed on side surfaces of a groove in which the first film is formed, as viewed in section.
(29)

The light detecting device according to any one of (22) to (26) above, in which
the structural body further includes a fourth film including a fourth material different from the first material, the second material, and the third material.
(30)

The light detecting device according to (29) above, in which
the fourth film is a conductor film.
(31)

The light detecting device according to (30) above, in which
the fourth material is a titanium-based compound.
(32)

The light detecting device according to any one of (29) to (31) above, in which
the third film is formed on side surfaces of a groove in which the first film is formed, as viewed in section, and
the fourth film is formed on a bottom surface of the groove.
(33)

The light detecting device according to any one of (29) to (31) above, in which
the third film is formed on side surfaces and a bottom surface of a groove in which the first film is formed, as viewed in section, and
the fourth film is formed at the bottom surface of the groove.
(34)

The light detecting device according to any one of (22) to (33) above, in which
the second film is formed so as to cover a part of the first film, and
the structural body is formed on side surfaces of a color filter, and formed in a lattice manner as viewed in plan for the color filter.
(35)

An electronic apparatus including:
a light detecting device including
   a plurality of pixels each having a photoelectric conversion region, in which
   a conductor is formed in an element isolation region formed in a semiconductor substrate in which the photoelectric conversion region is formed, and a potential is applied to the conductor, and
   a structural body is formed in a lattice manner as viewed in plan on the semiconductor substrate, the structural body having a first film including a first material, a second film including a second material different from the first material, and a third film including a third material different from the first material and the second material.

### REFERENCE SIGNS LIST

10: Solid-state imaging device
21: Pixel array unit
22: Vertical driving unit
23: Column signal processing unit
24: Horizontal driving unit
25: Output unit
26: Control unit
100: Pixel
101: Element isolation region
102: Antireflection film
103: Structural body
105: Groove
111: Photoelectric conversion region
112: First region
113: Second region
121: First layer
122: Second layer
123: Third layer
124: Fourth layer
125: Fifth layer
131: Low refractive index film
132: High refractive index film
141: Color filter
142: Planarizing film
143: On-chip microlens
200: Pixel
201: Element isolation region
202: Antireflection film
203: Structural body
205: Groove
211: Photoelectric conversion region
212: First region
213: Second region
221: First layer
222: Second layer
223: Third layer
224: Fourth layer
225: Fifth layer
231: Low refractive index film
232: High refractive index film
241: Color filter
242: Planarizing film
243: On-chip microlens
251: Insulating film
252: Conductor film
1000: Electronic apparatus
1012: Light detecting element

What is claimed is:

1. A light detecting device, comprising:
a plurality of pixels each having a photoelectric conversion region, wherein
a structural body is formed in a lattice manner as viewed in plan on a semiconductor substrate in which the photoelectric conversion region is formed, the structural body having a first film including a first material and a second film including a second material different from the first material.

2. The light detecting device according to claim 1, wherein
the first film is a low refractive index film in which the first material has a predetermined refractive index.

3. The light detecting device according to claim 2, wherein
the second film is a high refractive index film in which the second material has a higher refractive index than that of the first material.

4. The light detecting device according to claim 3, wherein
the second material is aluminum oxide (AlOx).

5. The light detecting device according to claim 1, wherein
the structural body has a structure that reaches an element isolation region formed in the semiconductor substrate, as viewed in section.

6. The light detecting device according to claim 5, wherein
the structural body has a structure that is thinner than the element isolation region as viewed in section.

7. The light detecting device according to claim 5, wherein
the structural body has a structure that is thinner than a region formed within the element isolation region, as viewed in section.

8. The light detecting device according to claim 5, wherein
the structural body has a structure that is thicker than the element isolation region as viewed in section.

9. The light detecting device according to claim 5, wherein
the structural body has a two-stage structure in which an upper portion and a lower portion are different in thickness from each other as viewed in section.

10. The light detecting device according to claim 9, wherein
the upper portion has a structure that is thicker than the lower portion.

11. The light detecting device according to claim 9, wherein
the upper portion has a structure that is thinner than the lower portion.

12. The light detecting device according to claim 1, wherein
the structural body has a structure that does not penetrate the semiconductor substrate as viewed in section.

13. The light detecting device according to claim 12, wherein
the structural body has a two-stage structure in which an upper portion and a lower portion are different in thickness from each other as viewed in section.

14. The light detecting device according to claim 13, wherein
the upper portion has a structure that is thicker than the lower portion.

15. The light detecting device according to claim 13, wherein
the upper portion has a structure that is thinner than the lower portion.

16. The light detecting device according to claim 1, wherein
the structural body has a structure that does not penetrate a part of layers of an antireflection film formed on the semiconductor substrate, as viewed in section.

17. The light detecting device according to claim 16, wherein
the structural body has a two-stage structure in which an upper portion and a lower portion are different in thickness from each other as viewed in section.

18. The light detecting device according to claim 17, wherein
the upper portion has a structure that is thicker than the lower portion.

19. The light detecting device according to claim 17, wherein
the upper portion has a structure that is thinner than the lower portion.

20. The light detecting device according to claim 1, wherein
the second film is formed so as to cover a whole of the first film, and
the structural body is formed on side surfaces of a color filter, and formed in a lattice manner as viewed in plan for the color filter.

21. An electronic apparatus, comprising:
a light detecting device including
a plurality of pixels each having a photoelectric conversion region, in which
a structural body is formed in a lattice manner as viewed in plan on a semiconductor substrate in which the photoelectric conversion region is formed, the structural body having a first film including a first material and a second film including a second material different from the first material.

22. A light detecting device, comprising:
a plurality of pixels each having a photoelectric conversion region, wherein
a conductor is formed in an element isolation region formed in a semiconductor substrate in which the photoelectric conversion region is formed, and a potential is applied to the conductor, and
a structural body is formed in a lattice manner as viewed in plan on the semiconductor substrate, the structural body having a first film including a first material, a second film including a second material different from the first material, and a third film including a third material different from the first material and the second material.

23. The light detecting device according to claim 22, wherein
the first film is a low refractive index film in which the first material has a predetermined refractive index,
the second film is a high refractive index film in which the second material has a higher refractive index than that of the first material, and
the third film is an insulating film.

24. The light detecting device according to claim 23, wherein
the second material is aluminum oxide (AlOx).

25. The light detecting device according to claim 23, wherein
the third material is silicon oxide (SiO₂).

26. The light detecting device according to claim 22, wherein
the structural body has a structure in which the third film insulates the conductor in the element isolation region from a dielectric included in an antireflection film formed on the semiconductor substrate.

27. The light detecting device according to claim 26, wherein
the third film is formed on side surfaces and a bottom surface of a groove in which the first film is formed, as viewed in section.

28. The light detecting device according to claim 26, wherein
the third film is formed on side surfaces of a groove in which the first film is formed, as viewed in section.

29. The light detecting device according to claim 26, wherein
the structural body further includes a fourth film including a fourth material different from the first material, the second material, and the third material.

30. The light detecting device according to claim 29, wherein
the fourth film is a conductor film.

31. The light detecting device according to claim 30, wherein
the fourth material is a titanium-based compound.

32. The light detecting device according to claim 29, wherein
the third film is formed on side surfaces of a groove in which the first film is formed, as viewed in section, and
the fourth film is formed on a bottom surface of the groove.

33. The light detecting device according to claim 29, wherein
the third film is formed on side surfaces and a bottom surface of a groove in which the first film is formed, as viewed in section, and
the fourth film is formed at the bottom surface of the groove.

34. The light detecting device according to claim 22, wherein
the second film is formed so as to cover a part of the first film, and
the structural body is formed on side surfaces of a color filter, and formed in a lattice manner as viewed in plan for the color filter.

35. An electronic apparatus, comprising:
a light detecting device including
a plurality of pixels each having a photoelectric conversion region, in which
a conductor is formed in an element isolation region formed in a semiconductor substrate in which the photoelectric conversion region is formed, and a potential is applied to the conductor, and
a structural body is formed in a lattice manner as viewed in plan on the semiconductor substrate, the structural body having a first film including a first material, a second film including a second material different from the first material, and a third film including a third material different from the first material and the second material.
